(19) United States
(12) Patent Application Publication
(10) Pub. No.: US 2013/0061914 A1
(43) Pub. Date: Mar. 14, 2013

(54) Flux capacitor solar cell module

(71) Applicant: Corbin Leroy Young, Atlanta, GA (US)

(72) Inventor: Corbin Leroy Young, Atlanta, GA (US)

(73) Assignees: Corbin L. Young - Investor Asset IP Trust, Atlanta, GA (US); Corbin Leroy Young, Atlanta, GA (US)

(21) Appl. No.: 13/573,391

(22) Filed: Sep. 13, 2012

Related U.S. Application Data
(60) Provisional application No. 61/573,909, filed on Sep. 14, 2011.

(51) Int. Cl. H01L 31/06

(52) U.S. Cl. 136/252

(57) ABSTRACT

A solar cell module (1) having solar cells (5) connected to high voltage output capacitor banks (8) which powers loads, frequency modifier capacitor banks (12) which provide controlled electro-magnetic energy during periods of dim light, base plate capacitor banks (21) which frees electrons in the solar cells (5) and electron source capacitors (28b) which fills an electron pool (5e) on top of the solar cells (5) that are all controlled by a computer module (27). The capacitors operating in a pulsating short circuit manner to achieve the highest electron energies. The phenomenons that are created are electron avalanches, multipaction, metastability and magnetic field generator effects all for extending electron energy decay time so that electrons can more efficiently tunnel. through the solar cell. The electon pool (5e) providing a reservoir of electrons to supply large currents. Module (1) is small, portable and has interchangeable attachment modules (36) for enhanced operations.

### CROSS-REFERENCE TO RELATED APPLICATIONS

This application claims the benefit of application 61/573,909 with filing date Sep. 14, 2011 and sole applicant Corbin Leroy Young.

### FEDERAL SPONSORED R&D STATEMENT

Not Applicable

### REFERENCE TO A “MICROFICHE APPENDIX”

Not Applicable

### BACKGROUND OF THE INVENTION

1. Field of Invention

The present invention relates to the energy industry, specifically solar cell technology.

2. Prior Art

There are many ways to derive work from a variety of energy sources on earth. The main purpose of all energy technologies is to create either motion or radiation. Most of today's energy sources require multiple steps in order to achieve its desired product. For example coal must be mined, transported, burned to boil water, steam needed to turn a generator and electricity transported over long distances. Gas products must be drilled, transported, separated and refined, stored, piped, burned to boil water and steam needed to turn a generator and electricity transported over long distances. All of this steps require energy and create energy loss. Today there are over a dozen energy sources that mankind uses with each having benefits and drawbacks over one another. There are five elements which represent all energy sources which must be overcome if an worry free energy future are to be achieved. These are lowest production cost, power output, cleanliness, energy source supply and storage and portability. Because of the unlimited abundance of sunlight solar energy and hydrogen fuel cells are at the forefront for abundant and clean energy production.

One man made method of generating both radiation and motion energy is that of a solar cell. In general a solar cell is a construction of two separate materials with different electron balances. These materials are known as conductive and valence materials in that one readily receives electrons and the other readily gives electrons up. In a solar cell, which essentially is a large electro-magnetic wave excited diode there exists a junction point between the electron positive material (valance band) and the electron negative material (conduction band).

Solar cells in general are made from thin layers of silicon with each layer being molecularly modified to enhance its electron and crystal lattice structure. In general the silicon layer which is doped with boron atoms represents the positive plate because boron has three electrons in its outer shell and is therefore electron (negative charge) deficient. The silicon plate which is doped with phosphorus atoms represents the negative plate because a phosphorus atom has five electrons in its outer shell. Because of these differences the positive-boron plate has voids in which other electrons can easily flow to and the negative-phosphorus plate has extra electrons which are easier to give up. Both the p-type and n-type silicon conduct electricity. The resistance of both types is determined by the proportion of holes or surplus elections. Therefore both types can function as resistors and they will also conduct electricity in any direction. When the plates are placed together a p-n junction is formed. This p-n junction is where the electrons cross over thus forming an electric field. Because of the difference in electrons and holes, current will only flow in one direction which is from the positive plate up to the negative plate which is radiated by sunlight. This junction determines the minimum voltage needed for electrons to cross from the p-plate to the n-plate. In general silicon requires a voltage of 0.5. When attached to a circuit the conductor with a bandgap towards zero has less resistance than the p-n junction and therefore provides the path of least resistance for the electron.

The sun provides the earth with electromagnetic waves at a variety of frequency (energy) levels, intensities and wavelengths. 1000 watts per square meter or 93 Watts per square foot is the standard universal measurement of how much energy that the sun can provide earth. Thus all of today's solar cell are based on this 1000 watts per square meter maximum. The thermodynamic efficiency limit of the conversion of sunlight to electricity is said to be 86%. This means that the maximum power that can be obtained is 860 watts per square meter. To date at least for single junction silicon solar cells maximum that has been reached is about 25% with 31% being the limiting theory. Efficiency limits for multi junction cells are 50% and hot carrier devices 70% with 50 to 65% of this limit being achievable in the field. However in field operations only 50% to 65% of Current silicon solar cells have consumer production model efficiencies ranging from 5% to 21% with 10% being the average conversion efficiency. Also the efficiencies of the cells are based on a cloudless day at the specified angle of 37 degrees with the sun at an angle of about 42 degrees above the horizon. Other factors such as 25 degrees Celsius temperature and air mass of 1.5 are also taken into account in which the real world conditions will vary considerably. So efficiency as measured over a day or week will be much different that the specified outputs. Because of these low efficiencies relatively large areas of solar panels are needed in order to provide ample power to a building structure. The power need for an average American home is 3,000 watts so a minimum of 225 square feet of solar panels weighing about over 600 pounds would be needed. Because silicon forms 27.7% of the earth's crust it allows a price low enough to be commercialized but still to high to be on parity with other electric generation fuels such as coal and natural gas.

Although the spectrum of electromagnetic waves varies from radio waves (low frequency, long wavelength) to gamma rays (high frequency, shore wavelength) solar cells in general can only use visible light and a little bit of infrared rays (lower frequency than visible light) and near ultraviolet rays (higher frequency than visible). Within the spectrum of visible light the different wavelengths are represented by different colors with the red and orange colors having the lower frequencies respectively and the blue and violet colors having the highest frequencies respectively. Solar cells work best with the blue and green waves of the electromagnetic spectrum which ranges from 425 to 525 nanometers in wavelength. The output of the sun's rays striking the earth is 4% ultraviolet light, 40% visible light and 56% infrared. Based on this distribution of light and the targeted blue-green frequency range it can be experimentally postulated that a percentage of the inefficiency solar cells is due to reduced amounts of the blue-green frequency level due to the large infrared component.

The maximum solar cell size is 6 inches by 6 inches and regardless of size roughly 0.5 volts open circuit voltage is all that can be produced from single junction silicon cells. Most research for solar cells has focused on the molecular structure of the n-p plates and their assembly configuration in order to enhance the electronic properties of the materials. A smaller percentage of research has focused on the current flow out of solar cells. One reason for this is that although voltage, current and (load) resistance are relative to one another, current is less relevant than voltage in operational terms. This is stated because it takes roughly 120 volts (U.S.) to operate a 120 volt rated appliance. Thus 120 volts will at least get the appliance operational (considering a minimum current). However the performance is purely dependent on current. A 100 watt light bulb needs I=P/V 100 watts/120 volts=0.83 Amps to operate at its rated brightness but can be operated with lower Amps for decreased light output. Although the light can operate at a lower voltage rating the percentage difference is greater for current than it is for voltage because voltage pressure must overcome the resistance (load) and until this resistance barrier is overcome, current in general is not allowed to flow to produce the targeted effect. A single solar cell can put out a relatively large 8 amps of current but because the voltage is 0.5 volts the current will not flow. Three solar cells therefore can produce enough current for a standard 25 amp home. The conclusion is that moving electrons is very easy for a single solar cell but high current and high voltage is not.

Solar cells operate because the suns electromagnetic rays impart energy to both the atoms and electrons of a material so that such vibrations loosen the electrons from their electrostatically and magnetically held positions. The bandgap energy is the amount of energy required to dislodge an electron from its covalent bond and allow it to become part of the electrical flow circuit and is measured in electron volts (ev). To free an electron the energy of the electromagnetic wave must be at least as great as the bandgap energy. Any more energy than the bandgap energy and this energy will be converted to excess heat. This discrepancy in energy results in silicon having to be tuned to the incident electromagnetic fields. Crystalline silicon has a bandgap energy of 1.1 electron volts. An electron volt is equal to the energy gained by an electron when it passes through a potential of 1 volt in a vacuum. The bandgap energies of other effective solar cells range from 1.0 to 1.6 which in this range electrons can be freed without creating excessive heat. The electromagnetic energy of light varies according to the wavelengths of light with the spectrum from infrared to ultraviolet ranging from 0.5 to 2.9 electron volts. For example, red light has an energy of about 1.7 electron volts and blue light has an energy of about 2.7 electron volts. Most solar cells cannot use roughly 50% of the energy of sunlight because this energy is either below the bandgap of the material used or carries excess energy. Solar cells with multiple bandgap absorber materials improve efficiency by dividing the solar spectrum into smaller bins where the thermodynamic efficiency limit is higher for each bin.

The construction of a solar cell is such that the bottom plate is made of a metallic conductor. On top of this is the p-type plate. On top of the p-type plate is the n-type plate. And on top of the n-type plate are conductors laid out to allow maximize sunlight to penetrate the plates but not so far apart as to lengthen unnecessarily the electron's path of travel. Thus when an electromagnetic wave mostly within the frequencies of visible light strikes the plates, electrons are vibrated out of their magnetic wells “holes” in the p-type plate, move across the p-n junction, into the n-type plate and on to the load via the top conductor (fingers). From the load the electrons travel to the bottom conductor plate where the remaining voltage pressure (voltage drop across the load) electrostatically pushes them back into holes of the p-type plate for the process to start over again. The end product being the creation of a magnetic field through electron movement, heat and pressure via circuit resistance.

Other factors of solar inefficiency which must be addressed are pollution, varying light frequencies due to atmospheric conditions and sun tracking which can greatly enhance power output but increase product costs. Also a compact scalable solar module for energy portability is useful as well as addressing the aesthetic issues of large areas of solar panels which relate to land costs.

In summary it can be concluded that the areas of solar cell technology that need improvement is the need generate maximum power at the blue green frequency level, to maximize the use of the relative high electrical currents produced by solar cells and to manipulate both the electrostatic fields and the bandgap energies so that electron flow amperage is increased in sight of high voltages. It is the intention of this invention to address and connect technologies within the solar cells to produce a maximum output wattage and reduce panel size and solar energy's overall costs.

### Objects & Advantages

There are several objects and advantages that this Flux Capacitor Solar Cell has over traditional solar cells. This application will demonstrate that the 1000 watts per square meter as universally accepted as the amount of energy reaching the earth is technically wrong and only relates to the application which measured it which is the diode. The Flux Capacitor utilizes a host of physics technics to achieve a large power output from a small cube package.
1. Frequency energy modifier: FIGS. 7A & 12 A-D. Solar cells (silicon) work best in the 450 to 550 nanometer wavelength area. The nature of frequencies (energy) is that material vibrating at a lower frequency will absorb the energy of a higher modulating material until equilibrium is reached. The fact that 57% of the sun's incident energy on earth is infrared means that the higher blue-green frequencies are being reduced which in turn reduces the energy conversion factor of the solar cell. The frequency energy modifier conductor radiates the conduction band of the surface of the solar cell with a particular frequency so that the final plate frequency is nearer to that of the ideal frequency for such specified material. The frequency of radiation is determined and modified by a computer constantly monitoring the circuit for changes in voltage and current. This frequency energy modifier conductor also allows for a more reliable source of electricity during periods of cloud cover between clear sunlight paths to the cell's surface.
2. Increased current flow: FIGS. 9, 10, 11. The Flux Capacitor Solar Cell increases current flow by using the short circuit nature of electronics circuits. This is most speedily, efficiently and safely done by using capacitors. Capacitors by nature are short circuit devices and can handle large volumes of electrons and can be connected to form larger voltages.
3. Increased Voltage to help dislodge electrons: FIGS. 22A & 22B. The objective is to produce a 120 volt (U.S.) output voltage at least 25 amps from each Flux Capacitor Solar Cell. High voltages can be created in a number of ways such as allowing a capacitor's high current to power an inductor used as a transformer. This 120 volts (or fraction thereof) can now be used to create voltage pressure on the base conductor plate to assist in dislodging electrons from their positions. Capacitors can also be wired in parallel and series configurations so that ideal output levels are realized. The computer will adjust the operations of the Flux Capacitor Solar Cell in real time for the correct combination of energy from the high voltage plate and frequency energy modifier while accounting for infrared heat.
4. Electromagnetic wave intensity stepper system: In a solar circuit the frequency of the electromagnetic wave which is its energy is responsible for dislodging an electron efficiently and the intensity of this energy is responsible for how many electrons get dislodged per given period of time. The frequency energy modifier is used to generate more efficient use of the sun's energy. This electromagnetic wave intensity stepper system is used increase the energy at such optimum frequency level with the result of increasing the electron current of the cell. The electromagnetic waves of the sun do not alternate exactly like an alternating current and are more comparable to a direct current. The frequency energy modifier uses a capacitor setup in which the anode stores the charge, the cathode receives the current and the conductor connecting the two acts as the frequency producer. Because any accelerating electron produces an electromagnetic field and because any pulsating circuit creates electromagnetic frequencies the electromagnetic fields coming from sunlight can in general be replicated. The stepper system is used in steps in which each step is a circuit cycle or group of circuit cycles. For example, the change due to the frequency energy modifier is 5% more efficient. A standard silicon cell is 10% efficient meaning that given a 25 square inch area the power produced is 1.6 watts. A 5% increase in efficiency would produce a gross gain of 0.08 watts. Subtracting circuit losses (during that cycle, the energy used in the frequency energy modifier and the energy used in the next cycle frequency energy modifier, any net wattage gain over 0 would produce a total cell gain. Because it produces a gain this process can be replicated over and over again until the total gross wattage of the cell is reached which is 16.12 watts. Thus the net wattage of the cell is circuit losses plus energy used to operate frequency energy modifier minus 16.12 watts. Any increase over a standard cell's gross 1.6 watts is results in a decrease of cell area. Any increase by a factor over a standard cell's gross 1.6 watts results in a reduction in price. This factor takes into account the costs necessary to produce the Flux Capacitor Solar Cell. When the excess area of a standard cell's cost exceeds the cost of the Flux Capacitor Solar Cell (minus silicon wafers, etc.) then the Flux Capacitor Solar Cell becomes more efficient in terms of energy production and costs.
5. Flux capacitor: FIGS. 12A-D. The flux capacitor of this Flux Capacitor Solar Cell technology is the regulator between the frequency energy modifier and the magnetic up electron pusher fields. It is necessary on four fronts. It sits above the solar cell in the center of the cell. One it receives the open circuit current pulses coming from the frequency energy modifier. Its capacitor is the cathode of the frequency energy modifier. The flux capacitor then discharges either in pulses or as a continuous current down through the diode layers of the cells. It discharges its current into a cathode which is connected to the base plate conductor. Because of this it acts as both a cathode for the frequency energy modifier and an anode for the electron volt enhancer. It is able to play dual roles either by circuit switching or because of the difference in capacitor voltage pressures between the to capacitor plates. Its third role is to regulate the current flowing through the frequency energy modifier via a resistance method. This resistance method works by allowing the capacitor of the Flux Capacitor to fill to varying levels of charge. This charge in turn creates a negative voltage pressure on the frequency energy modifier conductor so that the current is slowed (or allowed to speed up). Such control over the frequency and current allows greater precision in matching the correct electromagnetic frequency for the solar cell's atomic structure. The fourth use of the Flux Capacitor is to serve as a central station for all frequency energy modifier conductors. It routes the current from these into the vertical conductor tube which goes through the solar cell layers.
7. Base plate electron volt capacitor: FIG. 7A. The base plate electron volt capacitor provides a voltage pressure to the base plate in addition to the high (120) volt line piped into the base plate. So as to eliminate any negative voltage on the 120 volt line, an insulator gap exists between the 120 volt base plate and the section of the base plate with the attached capacitor. An electron overflow bypass gate back to frequency modifier capacitor anode exists. So as to maintain a proper voltage each capacitor of the base plate should be smaller than the capacitors of the flux capacitor. An optimum design is for the sum of the voltages across the capacitor base plate to be equivalent to the 120 volt plate taking voltage to area distribution into account. This capacitor base plate adds voltage to p-plate of the solar cells to assist with the dislodging of electrons. This base plate capacitor serves an important function in that it completes the circuit from the frequency energy modifier anode capacitor to the frequency energy modifier conductor to the flux capacitor then down through the plates and routed back up through the plates via the plate capacitors.
6. Capacitor current: The Flux Capacitor Solar Cell utilizes a capacitor based short circuit design to achieve the highest current flow with minimum voltage. There are two major circuits within the Flux Capacitor Solar Cell, the high current low voltage circuit which enhances electron flow through the solar plates and the low current high voltage circuit which outputs the usable 120 ac volts.
5. Magnetic electron pusher fields: FIG. 13. The Flux Capacitor utilizes two magnetic electron pusher fields. The purpose of these fields and their configuration is to assist in the efficient flow of electrons to the top conductor plate at the highest speed and voltage. This pusher field does not operate as a separate entity but is a by product of the current flowing through the high current circuit of the cell. Any electron moving parallel to the radial axis of a magnetic field incurs a force upon it. In this case the electron is considered relatively stationary and the magnetic field is expanding. The first of these magnetic electron pusher fields is created by the frequency energy modifier. Magnetic fields move from north to south. Thus if a current is moving from left to right the field area at the bottom of the conductor points towards the observer. Because the field is a pulsating field its (downward) accelerated expansion creates a relative movement between it and the electrons moving north through the cell plates. The moving electrons create an additional relative moving velocity. The end result is the generator effect in which the electrons are pushed towards the left towards the conductor edges of the cell which is the electron pool which adds additional voltage to them.

The second magnetic electron pusher field is created between the flux capacitor and the bottom of the lux capacitor conductor field up tube at the pipe conductor distributor. In this case the current is moving downward with the magnetic fields north direction pointing toward the observer on the left side of the conductor. The electrons located in the n-type plate, the p-type plate and the base conductor plate move relative to the magnetic field's y-axis only because of the field's accelerated expansion. Thus this conductor also has a pulsating current flowing through it. Based on the generator effect the electrons moving upwards from the base conductor plate are accelerated upwards even more. The combination of this upward acceleration and this outward (towards the rim) assists the electron velocity and therefore increases current towards the top conductor plates. This field also adds norther voltage pressure to the base plate capacitors. The third magnetic electron pusher field is created by the base plate conductor. This field puts downward pressure on the electrons in the high voltage output capacitor bank thus assisting in both electron voltage and capacitor capacitance and electron output voltage.
5. electron storage: FIG. 4B. The Flux Capacitor Solar Cell has batteries housed within its unit. Batteries serve two purposes. One is to provide start-up power to the computer, switching units and energy frequency modifiers and the other is to provide additional electrons to the circuit. By providing additional electrons to the circuit such as in the solar cell plates a greater voltage and flow of electrons through the plates can be achieved. Thicker plates can also be used as an electron source. When electrons flow through a conductor or material their magnetic field links with other electrons' magnetic fields and a pulling effect is created. FIG. 7A.
6. Final voltage output production: The objective of the Flux Capacitor Solar Cell is to produce a final usable AC voltage at the highest possible output (100% efficiency for these purposes). This voltage in the U.S. is 120 volts.
7. Modular Attachments: FIG. 25. The Flux Capacitor Solar Cell is a modular solar cell in that modular additions can be easily connected to it in various sequences. These additions can enhance the operations of the solar cell. These modules are attached to the underside of the cell or above the cell.
A. Light concentration module: By magnifying the intensity of sunlight, more power can be created in a smaller module. This module is used with the sun tracking module.
B. Lens cleaner module: The Flux Capacitor Solar Cell has an automatic wiper for self cleaning. This feature is useful for when the cell is placed in environmental conditions such as snow and in dusty areas like on construction sites. Dust particles can block out a significant amount of sunlight.
C. Automatic tinting and wavelength separation and reflection module: The sun's rays are comprised of 4% ultraviolet, 40% visible and 54% infrared light. This module serves the purpose of minimizing undesired wavelengths. It also serves the purpose of reflecting the waves from the electron pool for prolonged electron excitation at the desired frequencies (blue-green).
D. Cooling fan module and vacuum module: Most electronic devices operate more efficiently when operated at a cooler temperature. This fan based module can be upgraded to a liquid cooled or even a refrigerant cooled module. In order to reduce air temperature, a vacuum can be created in the module.
E. Computer module: The Flux Capacitor Solar Cell has an onboard processor within each module. This processor can be enhanced by connecting a computer connection module to it. This computer module will be able to operate all of the module attachments.
F. Payment module: The payment module allows for persons to pay for energy by the kilowatt. It is most efficiently done by either a microchip or entering a code on a remote access device.
G. Battery module: The battery module serves two purposes. It allows the module's computers and systems to turn on and it allows certain operations to occur more efficiently such as operating the frequency energy modifier at the start of operations. It also allows use of electricity for the internal systems when sunlight isn't available or is of poor intensity.
H. Multiple scaling module: A module for scaling up can be used which allows connectivity of the same or mixed and different rated Flux Capacitor Solar Cells. Thus a 12 volt dc cell can be used with a 120 volt ac cell to produce the desired current type and voltage.
I. Rectifier and inverter module: Depending on the cell the normal output of the module may be either AC or DC in voltage. If the normal output is AC (alternating current) then an inverter module can convert it to DC (direct current). If the normal output is DC then a rectifier module can convert it to AC current. Modules can also be used for travel to countries which use a different voltage system.
J. Multiple outlet module: This module allows multiple appliances to be connected to the module.
K. Transformer module: FIGS. 22A & 22B shows how the transformer attachment module can be used both to assist the Flux Capacitor Solar Cell in some of its “start-up” operations and how electricity can be flow trough the transformer to provide power to a device. Because transformers operate on alternating or pulsating current, the Flux Capacitor Solar Cell can use these frequency pounding electrons to free more electrons in the solar cell to fill the electron pool. This freeing of electrons will allow more electrons from the electron source block to enter into the cell and fill the electron holes left behind. Because no electrons leave (or enter) the module no electrons are lost to the circuit or grounding.
L. Wireless communication module: This module allows the Flux Capacitor Solar Cell to be controlled and monitored via cellular or satellite means.
M. Sun tracking module: This module connects with the sun intensity tracker to pivot the module perpendicular to the rays of the sun.

### Loss Mitigation

Over half of the energy losses in a solar cell are attributed to photons either not having enough energy to alter the electron-hole pair or photons having too much energy in which the remainder is converted to heat energy. The Flux Capacitor Solar Cell because it is a “smart” and “active” solar cell is able to minimize these effects through incremental controls throughout its operation.
a. reflectance—Reflectance losses are mainly fixed losses in that the solar cell face and panel cover will ultimately reflect some of the incoming light. Light has a variety of frequencies and intensities throughout the day. This and the combination of energy decay in the electrons and nuclei of the solar cell create an overall lower energy signature. An ideal solution is to modify some of the properties of the transparent cover to repel and accept various frequencies of both incoming and outgoing waves throughout the day accordingly. The tinting and wavelength separation attachment module will allow automatic precision control to both incident and emitted waves. The success or failure of various wavelength transfer modifications to the cover is determined by voltage output as measured by the onboard computer.
b. thermodynamic (conversion) efficiency—FIG. 19A & 20A. Today's mass produced solar cell efficiencies ranges from 8% to 20% in the field. When cost is factored in, higher efficiencies can be less efficient than the low efficiency, lower price cells. Because electrons take up a planar area and because the flux of electromagnetic waves through this area is 100%, efficiency can be looked at from different perspective. The atom has been determined to be full of empty space with the nucleus being the object with the most volume. In examining the material of silicon it has 14 electrons in 3 energy levels with 4 of the electrons being nearest the conduction band requiring only 1.11 electron volts to liberate it. Because the sun's incident energy is 1.24 ev this is not a problem. Even if all four of these electrons are utilized this results in a maximum conversion efficiency of 4/14=29%. If this is looked at from a flux perspective, the cross sectional area of an atom divided by the cross sectional area of an electron would equal the maximum conversion efficiency in which case as a comparison current solar cell efficiencies are far less than 1000 of 1%. The Flux Capacitor Solar Cell utilizes an electron pooling method that allows 100% of the flux radiating the area of the cell to be flooded by electrons in a small number of planes which means that goal is mainly electrons absorbing the incident waves instead of the nucleus of the atoms. By targeting 100% absorption of the incident electromagnetic waves by the electrons, heat energy will be reduced which in turn will allow an increased level of efficiency.
c. recombination losses—FIG. 13. Recombination of the electron to a hole or its original hole is of great importance. In a percentage of the cases, energy that is used to almost remove the electron from its place is lost when the electron falls back into that hole or another hole. Because there is a sharp drop-off in the minimum energy needed to move an electron these losses can add up. The end result is heat being released with no useful work produced from the electron. All electrons that have energy eventually must loose this energy and become locked into a magnetic hole. Because energy is both vibrational and translational the later provides a more constant solution. A high enough voltage pressure (translational) best created with pulses will allow electrons to move with more force and therefore more velocity through the solar cell to minimize the chances of even valance band holes being able to capturing electrons. It also provides direction. However because the solar cell is a slow point in the electrical circuit and because the p-n junction provides a bottleneck point the addition of a touchless method other than electron to electron pressure and impact collisions is ideal. The magnetic-up field of the Flux Capacitor Solar Cell provides this touchless method of providing a pulsing force to continuously help accelerate each electron through the p-plate, the p-n junction and on through the n-plate. Even with bottlenecks, this magnetic up field feature provides a time delay to any electrons that may exceed the reverse force of the collapsing field so that a larger percentage of electrons do not fall back to recombine.
d. electrical losses—FIGS. 22A & B. Electrical losses combine both resistive heat generation and resistive voltage drops. Conventional solar cells are direct current based. This means that a single electron must flow from the cell to the load and back to the cell again. Direct current is not ideal for long distance transmission. When put into perspective, because a solar cell regardless of size produces only about 0.5 volts of pressure, a small structure having about 100 feet round trip to a load is range equivalent to a high voltage direct current line run over the distance of several miles. Solar cells also depend on the return voltage applied to the base plate to assist the waves of the sun in dislodging electrons and also giving the electrons direction. The p-n junction is also a source of electrical loss. Because this 0.5 volts (which is the open circuit voltage) drops off because of line and load resistance the voltage's ability to provide direction and force to the electrons after entering the cell is substantially diminished. Heat is ultimately the by-product of current and not voltage per se. The Flux Capacitor Solar Cell in its ideal operations utilizes a high AC voltage low current method in which the electrons stay in the circuit of the module and transfers its energy to the building load circuit via transformer. This solves three problems in one. First in sight of electron energy decay preservation an alternating current is more ideal to preserve a higher energy level because of its in and out over a very short distance ability than direct current which must make a loop and incur more lower thermal levels of energy. Second because the module produces a final usable voltage (120 volts) no inverters are needed which typically have a 10% loss factor. Third alternating current provides for less heat resistive losses because the electron travels a much shorter distance than in a DC system.
e. bandgap—FIG. 14D. There are materials other than silicon that have a lower bandgap electron removal energy such as germanium with a bandgap of 0.67 while also having over twice the number of electrons of silicon at 32. A total of 22 electrons exist in the outer 2 of its 4 energy levels (silicon has 4 in the 3rd level). However silicon is in more abundance making up 27.7% of the earth's crust by mass and is thus cheaper. The incident waves of the sun have an energy of 1.24 electron volts with silicon at 1.1 volts. Because of this small 0.13 electron volt difference, there exists no room for additional energy to dislodge the remaining electrons in the second and first (ground) levels. Metals such as aluminum for example are good conductors and have a bandgap towards zero but for practical purposes 0.001 ev is stated in this application. This means that a low frequency energy can move electrons. Since the electron is the prime target in solar cell operation an ideal goal is to turn the semiconductor into a one way conductor. The Flux Capacitor Solar Cell utilizes all of the force features of voltage, electric and magnetic field and pulsing methods to raise and maintain the electrons in a (close to) 0 bandgap state. This means removing the electrons from their atoms and pooling them adjacent to the outflow conductors. This will initially cause a negative net energy production in that energy is used to remove electrons rather than power the load. In the end once the electron paths through the crystal structure are created, the electron pool will have a greater quantity of electrons entering into the pool than exiting the pool and other energy enhancing continuation features such as metastability, electron avalanche breakdown and multipaction effects will take hold and net output energy of higher quantities can be realized. Because the electron pool conductor edge has a bandgap of only 0.001 ev only a small amount of the incident sun's energy is needed to force the electron along this conductor. A pool of high energy electrons combined with the generator pushing effects of the frequency energy modifier will allow a greater voltage in the pool's conductor edge.
f. absorption and decay—FIGS. 15A-15G. The ideal goal of each electron is to absorb the correct frequency and maintain that frequency for as long as possible. Under general circumstances the time for decay is always longer than the time for absorption. Typically an electron will decay from a higher state to the ground state in about 10 nanoseconds which depends on its level of energy. In a standard solar cell it will have lost all of this energy in the relatively long circuit if not due to time travel it will be due to lower thermal energy mixing. The Flux Capacitor Solar Cell has functions to lengthen the decay time and circulates higher energy electrons as many times as possible. Features such as the frequency bypass conductor are there for the purpose of continuously mixing in high frequency electrons which bypass time delaying capacitors. Decay time is lengthened using the effects of metastability and system resonance. With metastability, decay time can be lengthened to up to 1 million nano seconds which allows a much longer circuit travel time while maintaining its original higher energy level. FIG. 13. With system resonance the capacitors and plates of the module are radiated with an ideal frequency of electromagnetic pulses that either maintains the level in the blue-green spectrum or at a level which allows easier elevation to this blue-green spectrum by the sun and to a less degree the frequency energy modifier conductor. Circuit travel velocity is dependent on the circuit length which depending on the module size is less than 5 inches and capacitor charge and discharge times. The final result of these three features is that if an electron enters the solar plates and its energy falls to 1 electron volt and a target 1.24 volts is needed then only 0.24 ev of the sun's energy is needed thus using only 20% of the electron's available capacity. This leaves the remaining 80% for other electrons. In the case of the electron pool, up to 4 other electrons at 1 ev can share this 80%. When factoring in the bandgap energy of the conductor rim of 0.001 then no additional energy is needed since the electron has 1/001=1000 times the energy needed to reenter the circuit. The more times the electron can cycle through the system with the most amount of energy the more the output energy can be raised due to more current (and power).

It should be noted that today's standard of measurement of the sun's power of 1,000 watts per square meter is based on a meter that uses a passive photodiode in which only free electrons and electrons near the conduction band are used. Because atoms have a lot more electrons available and aspects of time (absorption and decay) which can be negotiated are present, energy production is not limited to 1,000 watts per square meter.

### Electron Mobility Enhancements

Solar cells operate on the basis of bandgaps and potentials. Thus the n-plate situated between the p-n junction and the edge (finger) conductors allows the electron to move in the direction of least resistance. Since the conductor has a bandgap of 0.001, the p-n junction has a bandgap of 1.11 and the p-plate has available holes, the path of least resistance is through the finger conductors. Sighting this behavior the best motion is continuous forward motion and this motion should be as quick and as big as possible.
a. reduced electromagnetic wave (heat) loss—FIGS. 15B & C. Once an electron absorbs energy it starts to emit this energy to its surroundings with time being the primary barrier between its elevated energy level and the ground state. Because this energy must be radiated it is best to radiate it to another electron rather than to its surroundings. On a quantum scale the space between electrons is relatively large. FIG. 20A. All electromagnetic waves follow the inverse square law in that the intensity of the radiation is inversely proportional to the square of the distance from the source. That being said the ideal solution is to place electrons next to one another in order to absorb any radiated energy. Using spherical stacking the max number of electrons that can surround and touch a central electron is 14. Yet 28 electrons are needed to block all of the energy radiated from the single included electron. Thus if two electrons radiate at the same frequency energy, the radiation will be radiated in another direction which ideally is another electron. FIG. 14D. The electron pool of the Flux Capacitor Solar Cell allows this continuous radiation transfer to occur in that a corona of electrons will be allowed to radiate at rather low voltages which is ideal in order to stay around the work function of the material which can be as high as 4 electron volts. Although some radiation from the top layers of the electrons must exit, the goal is to route them to the pool's conductor edge as quick as possible with as little conductor resistance as possible. This is made possible by the generator effects of the frequency energy modifier which pushes the electrons in the pool outward towards the rim thus adding a voltage pressure element. The speed at which this occurs is important so that as the top layer radiates to space the next layer down i exposed by the sun's radiation. FIG. 8. The electrons are moved through the circuit with the greatest speed by having an ample number of electron fall fingers and thus the greatest conductor area possible. This is due to electrical resistance being lower in higher conductor cross sectional areas. Higher edge voltages are also obtained because the centered high voltage base plate conductor pushes electrons to the top of the pool at a higher rate than the outer edge positioned plate capacitors moves its electrons to the top of the pool. This electron decay radiation (out of the cell window) is delayed due to the phased radiation coming down from the frequency energy modifier.
b. metastability—FIGS. 15C-F. Long term stability of a higher energy state is achieved through metastability. Thus the typical decay time of 10 nanoseconds is extended by a factor of 100,000 to 1 million nanoseconds. The use of metastability is ideal so that electrons can radiate their energy to adjacent electrons which is also helpful in keeping electrons from falling back to their ground state to quickly. Once metastability is achieved each layer of top electrons can radiate the lower layer and so on. The entrapment between the work function energy barrier of the material, the magnetic up field and the electrostatic pressure due to the high voltage on the base plate allows the electrons to be closer together for increased radiation absorption. The end result is that creating a metastable situation will allow elevated energy levels to exist over a longer period of time thus resulting in the electromagnetic energy of the sun being able to be spread over a larger number of electrons thus producing more power output. If an electron has an energy of 1.11 electron volts which is radiated to the maximum 14 surrounding electrons then 1.11/14=0.0792 ev worth of energy is transferred. If the next electron also has 1.11 electron volts worth of energy this 0.0792 ev is added for a total increased energy of 1.189 ev. This results in 1.189/14=0.0849 transferred to each next electron. The next electron at 1.11+0.0849=1.194 ev. This transfer of energy from electron to electron calculates upwards until the 14th electron with further calculations being equal to the 14th calculation. Because of complexity, the energy transferred back inward to the initiating electron and thus its subsequent reradiation have not been factored in. The end result is a very well sustained pool of highly energetic electrons which increases voltage pressure. In the end radiation energy must move either through physical particles or through space. Capturing this energy in a particle (and using it) increases energy efficiency.
c. electron avalanche breakdown—FIGS. 17B & 18A. If free electrons are being created at a rate greater than they are being captured by holes their number rapidly multiplies and obtains exponential growth. Depending on several factors the degree of multiplication can be several million fold. This process is necessary for the electrons that are in lower energy states to be moved to a higher state and thus be removed from the atom's hole. At these energies the frequency energy of visible light is exceeded and move into the near ultraviolet light range up to 12.4 electron volts. Thus ideally almost full ionization of an atom can exist. The Flux Capacitor Solar Cell is able to create this electron avalanche process through its use of high voltage pulses from the base plate and its ample electron source. Utilizing certain circuit designs, capacitor pulses of thousands of volts can be achieved for a single 6×6 inch module. This high voltage combined with the magnetic up field and the abundance of holes will reduce the collision energy required thus enhancing this effect even more. This avalanche of electrons will allow layers of electrons to corona near and on the surface of the electron pool. Subsequently this corona of electrons on the top of the pool (and within the plates) will emit ultraviolet radiation which will in turn intensify the avalanche. The ability of the electrons to avalanche can result in decreased energy need via less voltage on the base plate which can be redirected as output. This avalanche feature would only be used intermittently so as to reduce the excited frequencies from the ultraviolet range to the blue-green visible light range.
d. multipaction effect—FIG. 18A. The multipaction effect has similar outcomes as the electron avalanche effect in that multiples of electrons are released. Whereas electron to electron collisions are used in an electron avalanche via a pulsating voltage from the base plate a pulsating parallel moving electromagnetic field is used in this case. Utilizing the electromagnetic field allows an entire plane of electrons parallel to and within the solar plate to initiate multipaction which will increase the number of free electrons even more. Whereas the electron to electron impact ionization process is based on the probability of an electron striking another electron within x period of time, the electromagnetic up field gives 100% force coverage to the entire plate. Proper resonance is a key aspect of continued multipaction which can be tuned as needed via current pulse cycles from the flux capacitor. Also the use of the magnetic field allows a greater level of guidance of the electrons to the electron pool thus forming in plate electron paths through the crystal structure and reducing head on collisions with nuclei. This electric field will allow the electrons to stay elevated above their original and subsequent holes longer which allow more electrons from the base plate to fill these holes which subsequently decreases plate resistance. This either increases voltage pressure or the voltage pressure can be decreased. Once this is achieved a stacking method forms which requires less energy to maintain with the end result being that the saved energy can be redirected to the load. Thus the electromagnetic field combined with the base plate electric field provides and even greater efficient use of electrons. The more energy an electron has when placed in the electromagnetic waves of the sun the less of the sun's energy it needs.
e. work functions and bandgaps—FIG. 14D. Electrons must keep within at least two bounds. One they must have enough energy to overcome resistances and two they must not have too much energy or they will depart the surface. To prevent the electrons in the electron pool from escaping a combination of using the resistance of the module's transparent sun ray material, using a vacuum and keeping the electron energy low. Thus the goal is to have a single electron layer sheet of “lightning” on the surface of the cell. Electron energy is measured in electron volts (ev). An electron volt is the amount of energy required for an electron to overcome a one volt barrier or the amount of energy gained by an electron passing through a potential difference of 1 volt. The work function is the amount of energy required to move an electron to a point immediately outside a solid surface. The bandgap is the point in a material which has no electrons and a specific amount of energy is required for it to pass this point. Metals have low bandgaps, insulators high bandgaps.
A. The work function for aluminum is 4.26 ev
B. The emited energy for a metastable electron is estimated to be >2.24 ev
C. The work function for silicon is 4.85 ev
D. The bandgap for a electron on the surface of an electron is <0.000
E. The bandgap for silicon is 1.11 ev. The release energy for a ground state electron is 12.4 ev
F. The bandgap energy for aluminum is <0.001 (bandgap is actually less)
G. The energy level for sunlight 1.24 ev
H. The energy level for an avalanche electron can range based on voltage pulses <2 to 4 ev+
f. electron source—FIG. 3. The electron pool filled via the electron avalanche and the multipaction effect and sustained by metastability require a substantial number of electrons. Although by ionizing the silicon atom fully the number of electrons can increase manifold, in order to gain the highest power use an additional electron source is ideal. Most electrons in a circuit are needed by that circuit in order to function to specifications. This is because circuits are mainly collision based in that electrons push one another out of holes and the occupy that hole itself until it is pushed out. In general electrons do not need to be in a circuit to move and in this case the velocity of movement is not an issue. The Flux Capacitor Solar Cell has two electron sources. The first is the battery source. In the module are four battery compartments in the corners. With the ground terminal serving the purpose of supplying electrons to the battery, electrons can readily flow out to an empty capacitor. The second source is a radiated silicon or germanium, etc. electron source block. This electron source block is connected via a conductor and switch gate to the base plate. Because it sits adjacent to the magnetic up field the energized electrons which have met their minimum bandgap requirements now have direction. This is ideal because a voltage would only supply more electrons to the block. Ideally a low bandgap high electron material should be used. Once the electrons exit the block the computer cuts the switch to prevent backpressure from the baseplate voltage and thus reentry of electrons. This can also be achieved via diodes and other magnetic gate switches. The end result is that the electrons have no where to go but to exist in the electron pool. Once the solar cell shuts down (at night) the electrons are routed back to the block. A third source of electrons can be in the form of a gas. A vacuum chamber is placed over the electron pool and conductor edge. The flowing corona of the electron pool will emit photons of a certain energy and begin to ionize the gas and draw electrons from it. These electrons can be captured via the underside of the top of the module.

### Power Output

The power output can be observed in drawing sheets 19, 20 and 21.
a. The diameter of an electron has been measured to be 58.358 attometers. The diameter of the nucleus of a silicon atom is measured to be 4,522,000 attometers. Thus the cross sectional area of an electron is 2,675 square attometers and for the nucleus it is 16,060,201,777,862 square attometers. If the “square” area of an electron, 3405 square attometers is divided into the area of the cross sectional area of the nucleus the factor is 4,715,74,752. This is the number of electron areas that are shadowed by the nucleus and demonstrates why conventional static solar cells are made to be as thin as possible. This is because 90% of the light only penetrates 0.5% of the thickness of a 180 micrometer thick solar cell. This is the reason why thin film solar cells are used which are only 1 micrometer thick (4504 atoms) in which 90% of the light is captured. This are less efficient than standard sawn solar cells. FIG. 20D. The number of atoms that can fit in a 4×4 inch one atom layer area is 3.16×e67. The number electrons that ca fit in a 4×4 inch one electron layer is 4.58×e80. In summary, if the areas of the shadows were filled with electrons a far greater number of electrons would be excited. The most logical solution is to place electrons on top of the nuclei.
b. FIG. 20A demonstrates how an electron moved to any position in an x and z plane will experience the same amount of electromagnetic wave excitation at each position. The only change in energy levels occurs when the electron is brought closer to the radiation source which increases its energy level or moved further away which decreases its energy level which follows light's inverse square law. Thus the measure of a photon is the measure of the cross sectional area of each electron. It can now be said that the number of photons that are available to excite an electron is equal to the number of electrons within an area (4 inch by 4 inches).
c. intrinsic energy—FIG. 21C shows how an electron experiences a voltage force of at least 0.5 volts when excited by sunlight. This can be observed because voltage output in a solar cell is constant regardless of size and only current is affected. Thus as FIG. 21B shows, a solar cell divided into 240 small cells can produce 120 volts but only 0.033 amps whereas a whole 4×4 inch solar cell can produce 0.5 volts at 8 amps. The end result is Power=Voltage×Current=4 watts for each scenario. Because an electromagnetically radiated electron has achieved an intrinsic voltage state (as opposed to a linear voltage state which occurs via generators and power sources) power output is now only limited by the size of the cell and the number of electrons on top of that cell. This is further reinforced by the equation I=V/R which shows that a linear voltage of 0.5 volts and an arbitrarily low resistance of 0.000001 ohms can push 50,000 amps. Although 50,000 amps is not possible because of the breakdown of the material due to heat the equation is valid. Also this equation is based on linear voltage in which the electrons are pushed and not intrinsic voltage.
d. power boosting—FIG. 21D and 22D shows how power output can be boosted by wiring capacitors in a parallel manner. If each of these capacitors is connected to a solar cell then each capacitor would be able to charge to a voltage of 0.5 volts and have a lower end output of 0.25 volts. Based on a 4 inch by 4 inch solar cell area and the 120 voltage need, 240 solar cells at 0.25 inches by 0.25 inches are needed (In practice these cell would be pie sliced, FIG. 8C. This is because voltage is a constant in a solar cell regardless of size. The number of electrons that can fit within a 0.25×0.25 inch area in one electron layer is 1.79×e78. The standard house needs 25 amps which means 25 amps/240 cells=0.104 amps per cell or 2.15×e13 electrons per second. The number of electrons per second is then multiplied by the number of seconds in a day which is 86,400. The total number of electrons required per 0.25×25 inch cell is 1.86×e18. The percentage of electron capacity used is 9.09×e-25. This shows that at the very least a daily reservoir of electrons can be created to supply direct power and for hydrogen creation for fuel cells. And with a silicon melting point of 2577 degrees Fahrenheit a large number of electrons can be held in the electron pool.

It can be concluded that the by utilizing the additive methods of capacitors, voltage can be increased without being limited by size because voltage in a solar cell is a constant. It can also be concluded that because the sun is “guaranteed” to shine everyday or at least every week the number of electrons that can fit on the top of a solar cell as compared to the current need is irrelevant. Because each electron carries an intrinsic voltage to move itself a final statement that can be made is that “The Flux Capacitor Solar Cell's power output is only limited by the heat capacity of its materials”.

### SUMMARY OF THE INVENTION

The Flux Capacitor Solar Cell is an electronically enhanced solar cell. The Flux Capacitor Solar Cell is operated by computers and capacitors. The operational basis of the Flux Capacitor Solar Cell is to maintain a controllable short circuit mechanism so that voltages and hence currents are maximized. This maximization of power allows such high energy electrons to tunnel through resistive barriers in both the external loads and that of the solar cell. The end goal of the Flux Capacitor

Solar Cell is to create a source of power that is only limited by the heat capacity of the materials. This is accomplished by the creation of an electron pool on the top of the solar cell. Volume wise, a four inch by four inch electron pool can hold enough electrons in just one electron layer to power a 100 amp house indefinitely. Because voltage is a constant regardless of solar cell size, a solar cell sliced in 240 wedges and wired as needed is able to supply the 120 volts required to overcome the resistance of all of the electronics in a large house. And because electromagnetically excited electrons contain an intrinsic voltage and is the electric current an event of singularity exists. The Flux Capacitor Solar Cell merges these two facts of the physics of electron current and electron voltage to accomplish its goal.

The Flux Capacitor Solar Cell's high current and high voltage sections being incorporated into a compact modular design located vertically beneath the solar cell provides the most efficient method of electric generation and because of this, it exists as a ready to use final power source. Additional modules are able to be attached to it so that enhanced functions are realized. Because of this compact design the inefficiencies created with circuit length are eliminated. The Flux Capacitor Solar Cell addresses all of the issues which limit efficiency such as reflectance, thermodynamic conversion, recombination, electrical losses, bandgap energy requirements and energy absorption and energy decay. As a result, solutions such as a flux capacitor electron frequency modifier, metastability, electron avalanche breakdown, the multipactor effect, the generator effect of magnetic fields and additional electron material sources have been incorporated into the function of the module. And with the full use of electric current speed, voltage pressure, electric and magnetic fields a greater percentage the sun's incident energy can be utilized. In conclusion, the Flux Capacitor Solar Cell eliminates the 1000 watts per square meter rule that current passive solar cells must abide to and is able to provide much more power in which heat is the only limit to this power.

### Claims Definitions

The wording of the claims allows for a latitude of alternate substitutions and are not limited to the following examples.
a. resistive load—The terminology of resistive loads represent any device or circuit feature that resists electron current. This can include resistors, inductors and capacitors as well as energy storage and energy production devices.
b. electron power—The terminology of electron power represents any device or circuit feature that can supply electrons to any functioning feature of the module.
c. electromagnetic energy—FIGS. 16A and 16B. The electromagnetic spectrum ranges from long waves to gamma rays. In general the portion of the spectrum will range from infrared to visible light to ultraviolet light which is from the sun. All frequencies of the spectrum can be produced by artificial means.
d. computer means—The terminology of computer means references any single information chip or compilation of elements which has instruction storage and execution abilities. It also has the ability to process information and store and/or execute instructions based on this processed information. This includes both reactive and active computer means.
e. electron storage means—The terminology of electron storage means mainly represents capacitors in that electrons can enter into the capacitor, be held and released. Batteries, energy storage in a magnetic field and radiation storage in a material are also candidates for this term although capacitors are most efficient and effective in dealing with large quick bursts of energy.
f. electron conduction means—The terminology of electron conduction means refers to any means or method used to transfer electrons from one position to another. In general all materials or atoms for that matter are conductors as well as gases. If the interior of the module is a vacuum then the voltage difference between two conductors is the conductor means.
g. current manipulating gate means—The terminology of the current manipulating gate means is any operable switch not limited to material based switches, voltage based, electrostatic field, electromagnetic wave or magnetic field switches which purpose is to allow from zero to any number of electrons through it. These elements can act on materials or act on the electrons directly. Other elements such as resistors, diodes and those of like function manipulate a circuit in that current can only flow in one direction.
h. volume of material—The terminology of volume of material refers to any combination of materials and molecules. The volume of material is radiated by the electromagnetic source most notably the sun. In general all materials contain electrons and so all can serve in place of the solar cell if a unidirectional voltage is applied it. This conforms to the nature of the solar cell which is a diode with the purpose of allowing current to only flow in one direction. A voltage pressure on the bottom of any material will allow the continuously excited electrons to move out and into the electron storage means (capacitors).
i. power source—The terminology of power source mainly refers to a separate source of electricity such as a battery which could be incorporated in the module FIG. 4B. It also refers to external sources of electricity. Such power sources can provide electricity to the computer and other operating elements of the modules as well as adding and supplementing electrons to the conductors. Power source can also relate to a functioning element in the circuit deriving energy from one of the energy storage means, i.e. capacitors.
j. access means—The terminology of access means refers to an electron being able to approach a point, enter at a point, exit at a point or enter and exit at the same point.
k. control means—The terminology of control means refers to the ability of the computer means to dictate what a functioning element will do. This control means can be via physical and/or electromagnetic wave means at the time of instruction or delayed after the time of instruction by the computer means. In general the current manipulating gate means or switches of the circuit is what is being controlled for this is the only means of electron movement.
l. interconnectable circuit—The terminology of interconnectable circuit refers to a circuit that has the means to connect with further circuits with the end result being a single circuit in which at a time a point in that circuit electrons may flow and at the same time and different place electrons may not flow. Thus circuit is leans more towards potential ability than present operational ability of every point in that circuit.
m. means to allow—The terminology of means to allow refers to any barrier of electron transmission from one material(object) to another is overcome by a factor of another material, shape, position, function, etc. The means to allow being a possible combination of several factors.
n. functioning means—The terminology of functioning means refers to any part of the module which has a specific purpose and can perform according to that purpose whether self enabled or enabled externally. The result being that it functions in doing what it was designed to do.

### DESCRIPTION OF THE FIGURES

FIG. 1: Flux Capacitor Solar Cell Module.

FIG. 2: Section view of Flux Capacitor Solar Cell Module without electron avalanche source.

FIG. 3: Section view of Flux Capacitor Solar Cell Module with electron avalanche source.

FIG. 4a: Section view of Flux Capacitor Solar Cell Module.

FIG. 4b: Plan section view of top layer of Flux Capacitor Solar Cell Module.

FIG. 4c: Plan section view of bottom layer of Flux Capacitor Solar Cell Module

FIG. 5a: External plan view of Flux Capacitor Solar Cell Module.

FIG. 5b: Plan section view of electron pool.

FIG. 5c:: Section view of Flux Capacitor Solar Cell Module.

FIG. 6a: Current flow views of module.

FIG. 6b: Resistance load diagram.

FIG. 6c: Induction load diagram.

FIG. 6d: Capacitance load diagram.

FIG. 7a: Electromagnetic field views of module.

FIG. 7b: Current flow view of solar cell electron pool edge junction.

FIG. 7c: Current flow view through solar cell of base plate capacitors.

FIG. 8a: 3D view of electron pool and fall fingers.

FIG. 8b: Top view of electron pool.

FIG. 8c: Top view of electron pool in slices.

FIG. 8d: Electron pool slice.

FIG. 8e: Plan view of solar cell base plate.

FIG. 8f: 3D view of magnetic up field tube and solar cell base plate junction.

FIG. 9a: Battery charging frequency energy modifier capacitor and turning on computer circuit flow diagram.

FIG. 9b: Capacitor powering frequency energy modifier conductor circuit flow diagram.

FIG. 9c: Sunlight charging AC output capacitor positive ½ cycle 0.5 volts per capacitor circuit flow diagram.

FIG. 9d: Sunlight charging AC output capacitor negative ½ cycle 0.5 volts per capacitor circuit flow diagram.

FIG. 10a: Positive ½ cycle AC capacitor discharging to power load circuit flow diagram.

FIG. 10b: Negative ½ cycle AC capacitor discharging to power load.

FIG. 10c: AC output capacitor discharging to charge frequency energy modifier capacitor with a high voltage circuit flow diagram.

FIG. 10d: Voltage pressure on base plate (and sunlight) producing electron current through solar cell to charge AC output capacitor.

FIG. 10e: Graph of alternating current capacitor discharge frequency.

FIG. 11a: Direct current output positive ½ cycle AC capacitor discharging to power load circuit flow diagram.

FIG. 11b: Direct current output negative ½ cycle AC capacitor discharging to power load circuit flow diagram.

FIG. 11c: Graph of direct current capacitor discharge frequency.

FIG. 12a: Vertical section of Flux Capacitor Solar Cell Module.

FIG. 12b: Frequency energy modifier charging flux capacitor circuit.

FIG. 12c: Flux capacitor regulating current via reverse voltage pressure circuit.

FIG. 12d: Flux capacitor creating magnetic electron flow field and charging solar cell base capacitors. Base capacitors applying voltage pressure to base completing circuit.

FIG. 13: Electron avalanche breakdown and multipactor effect creation.

FIG. 14a: Prior Art. Diagram of a conductor with incident electromagnetic energy on it in a circuit. Current flows in both directions.

FIG. 14b: Prior Art. Diagram of a semiconductor with incident electromagnetic energy on it in a circuit. Current flows in one direction

FIG. 14c: Prior Art. Diagram of a insulator with incident electromagnetic energy on it in a circuit. No current flows.

FIG. 14d: Diagram of an electron avalanche in either a conductor, semiconductor or insulator with electrons pooling at the top held in a voltage trap.

FIG. 15a: Model of a silicon atom.

FIG. 15b: Figure of electron energy loss (decay) from a particle.

FIG. 15c: Figure of particle metastability.

FIG. 15d: Figure of low density electron which is representative of today's solar cell output.

FIG. 15e: Figure of medium density electrons which is representative of electron storage.

FIG. 15f: Figure of maximum density electrons which are representative of metastability.

FIG. 15g: Graph of electron decay time after metastability.

FIG. 15h: Graph of normal electron decay time without metastability.

FIG. 15i: Circuit travel time for electrons through Flux Capacitor Solar Cell.

FIG. 16a: Graph of the electromagnetic spectrum of sunlight which strikes the earth.

FIG. 16b: Electromagnetic wave spectrum.

FIG. 17a: Generator effect created by moving non collision elections.

FIG. 17b: Electron avalanche from electron collisions.

FIG. 18a: Figure of metastability creating a reservoir supply, multipaction, and electron avalanche in a material.

FIG. 18b: Prior Art. Figure of no electron reservoir supply in today's solar cell.

FIG. 19a: Figure of sun radiating the top of a solar cell with maximum electron density.

FIG. 19b: Prior art. Figure of sun radiating the silicon solar cell's nuclei and electrons in multiple layers.

FIG. 20a: Figure of electron positions and energy absorption under a electromagnetic wave source.

FIG. 20b: Figure of electron diameter and area.

FIG. 20c: Figure of silicon nucleus diameter and area.

FIG. 20d: Figure of area of silicon nucleus shadowing an electron.

FIG. 21a: Prior art. Four inch by four inch solar cell.

FIG. 21b: 240 0.25 by 0.25 inch solar cells in a four inch by four inch area.

FIG. 21c: Figure of an electron's voltage pressure from sunlight radiation.

FIG. 21d: Prior art. Figure of solar cells in series. Voltage is additive.

FIG. 21e: Prior art. Figure of solar cells in parallel. Current is additive.

FIG. 22a: Section view of Flux Capacitor Solar Cell Module with transformer module attachment.

FIG. 22b: Plan view of transformer module attachment.

FIG. 23a: Flux Capacitor Solar Cell Module wired in parallel.

FIG. 23b: Flux Capacitor Solar Cell Module wired in series.

FIG. 23c: Flux Capacitor Solar Cell Module capacitor banks wired in parallel and connected to individual solar cells. Voltage is additive.

FIG. 24: Time graph of Flux Capacitor Solar Cell Module start-up process.

FIG. 25: Figures of attachment units for the Flux Capacitor Solar Cell Module.

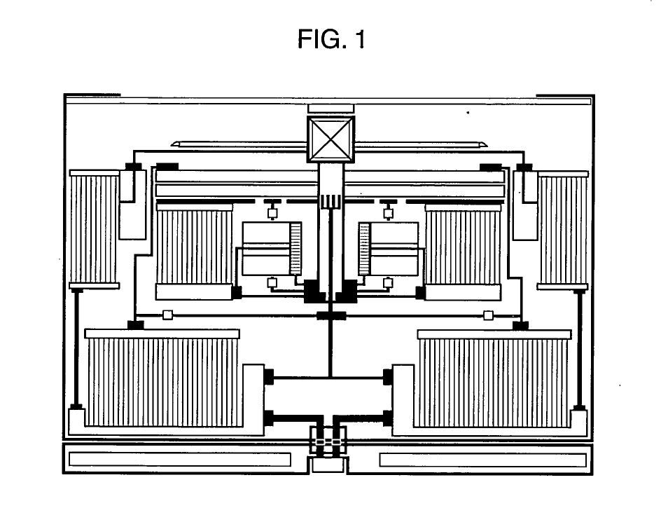

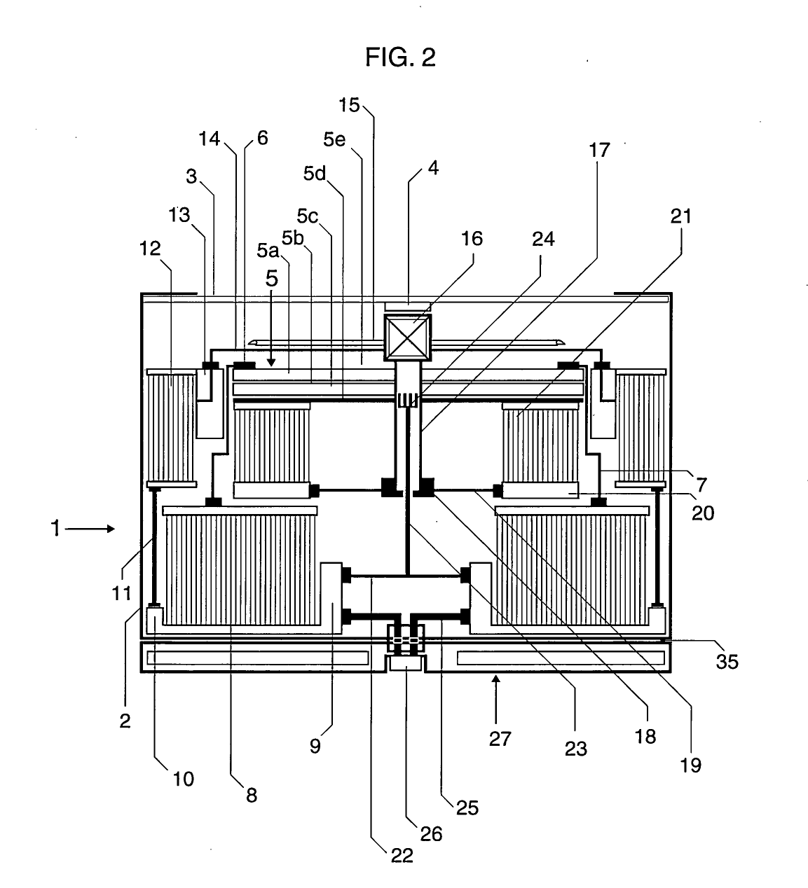

DESCRIPTION OF FIGURE REFERENCE NUMERALS

| | |
|---|---|
| 1. module | 2. module shell |
| 3. transparent cover | 4. sun intensity tracker |
| 5. solar cell | 5a. positive layer |
| 5b. pn junction | 5c. negative layer |
| 5d. base | 5e. electron pool |
| 6. electron pool conductor edge | 7. output capacitor charging conductor |
| 8. high voltage output capacitor bank | 9. high output capacitor switching bar |

| | |
|---|---|
| 10. frequency modifier capacitor switching bar | 11. frequency modifier charging conductor |

| | |
|---|---|
| 12. frequency modifier capacitor banks | 13. frequency modifier switching bar |
| 14. frequency modifier conductor | 15. frequency modifier field reflector |
| 16. flux capacitor | 17. flux capacitor conductor field up tube |
| 18. pipe conductor distributor | 19. base plate capacitor conductor |

| | |
|---|---|
| 20. high voltage base plate capacitor switching bar | 21. base plate capacitor |

| | |
|---|---|
| 22. base plate feed in conductor | 23. base plate conductor |
| 24. high voltage distribution gate | 25. high voltage output conductor |
| 26. module power transfer connector | 27. computer module |
| 28. electron source block | 28a. electron source material |
| 28b. electron source capacitor | 28c. electron source output conductor |
| 28d. electron source output switching bar | 28e. electron source input switch |
| 28f. electron source input conductor | 28g. electron source capacitor input conductor |
| 28h. electron source base plate switch | 28i. electron source base plate conductor |
| 28j. electron source base plate gap | 29. frequency bypass conductor |
| 30. frequency bypass conductor switch | 31. frequency bypass conductor distributor |
| 32. battery compartment | 33. electronics compartment |
| 34. magnetic field shielding | 35. data connection |
| 36. attachment modules | |

### DETAILED DESCRIPTION

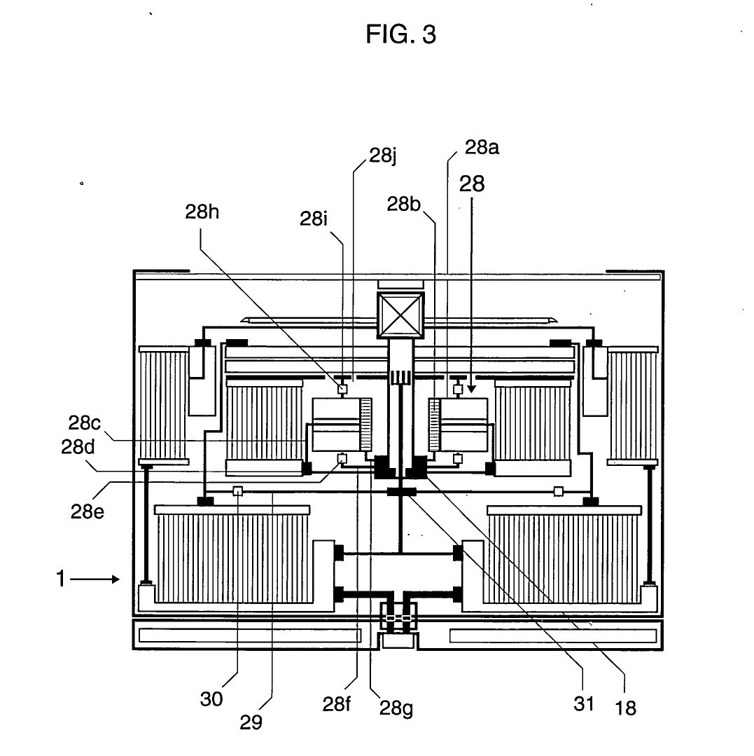

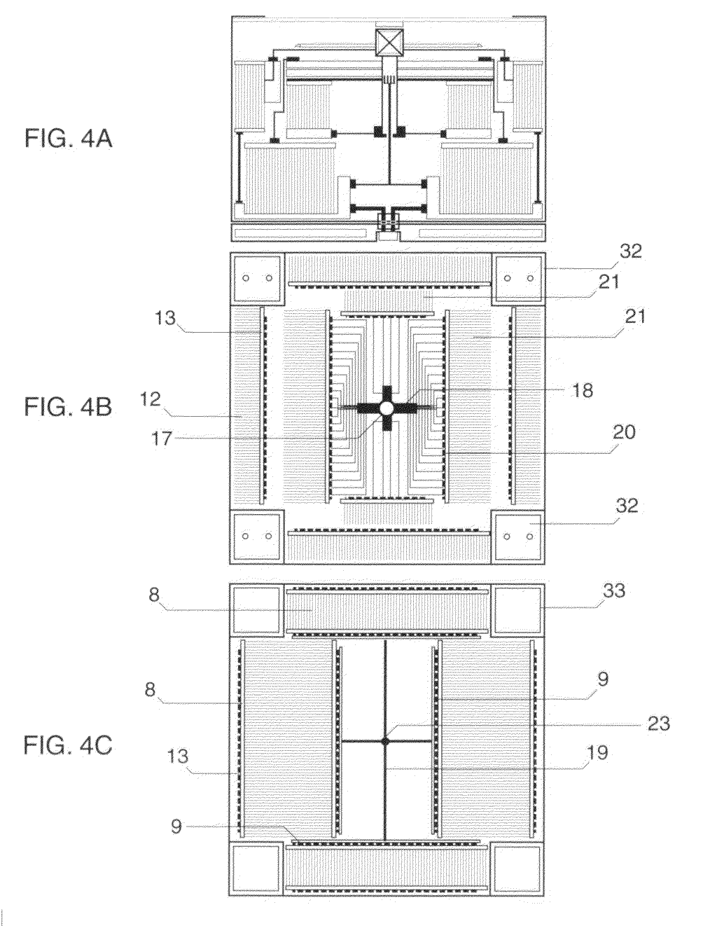

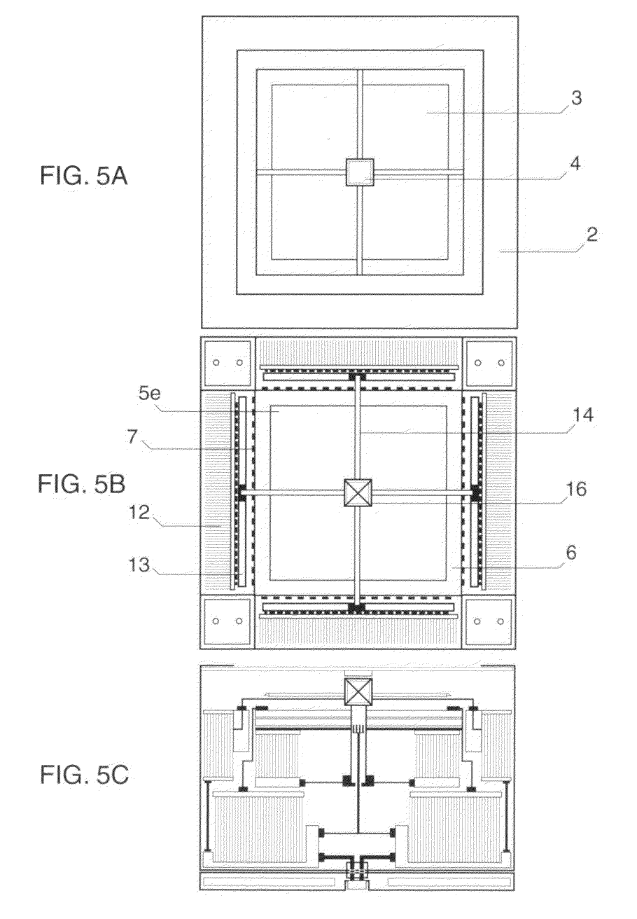

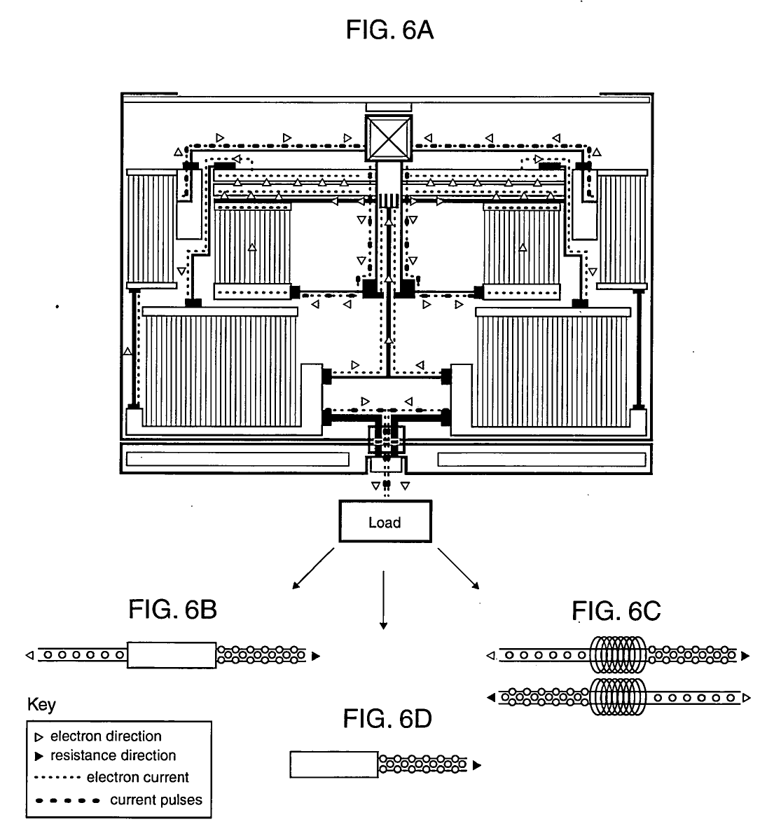

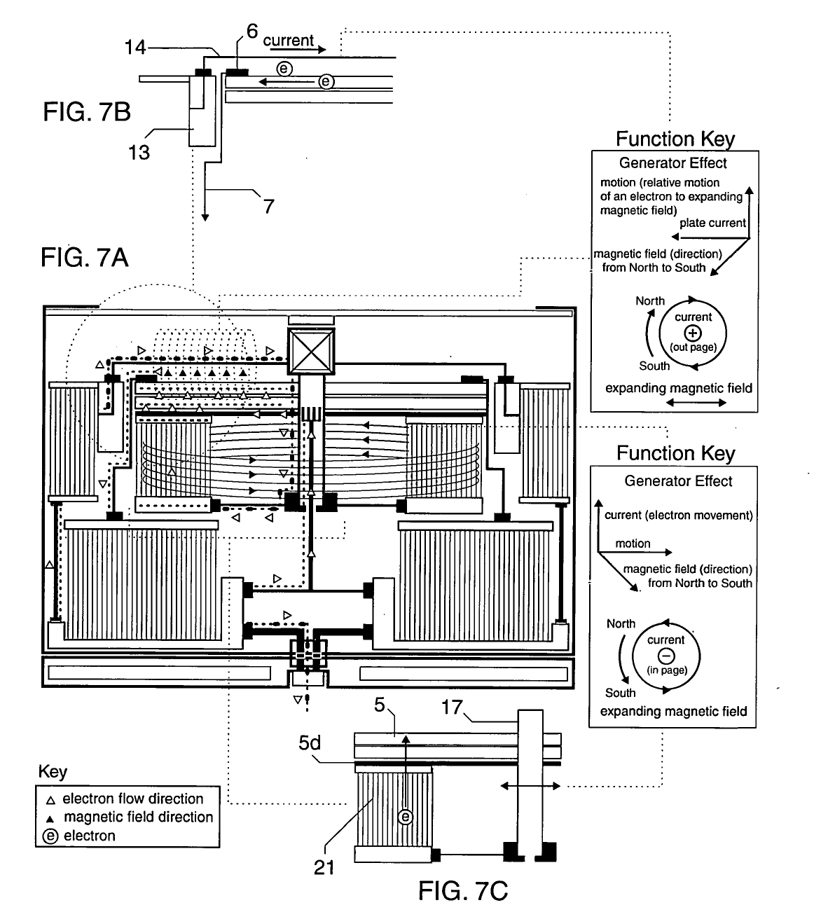

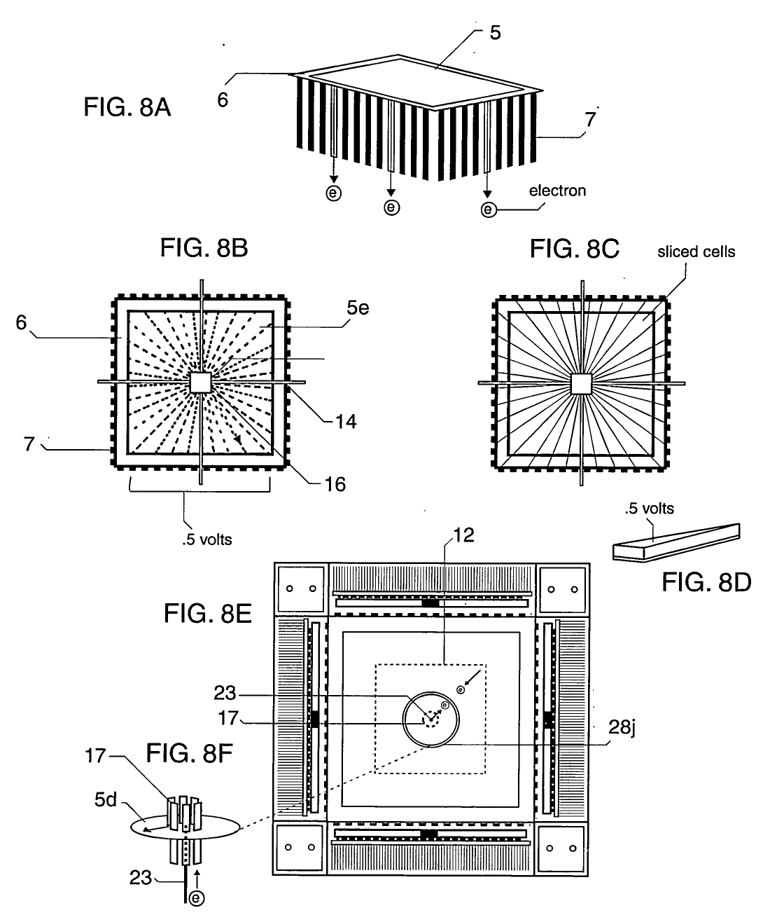

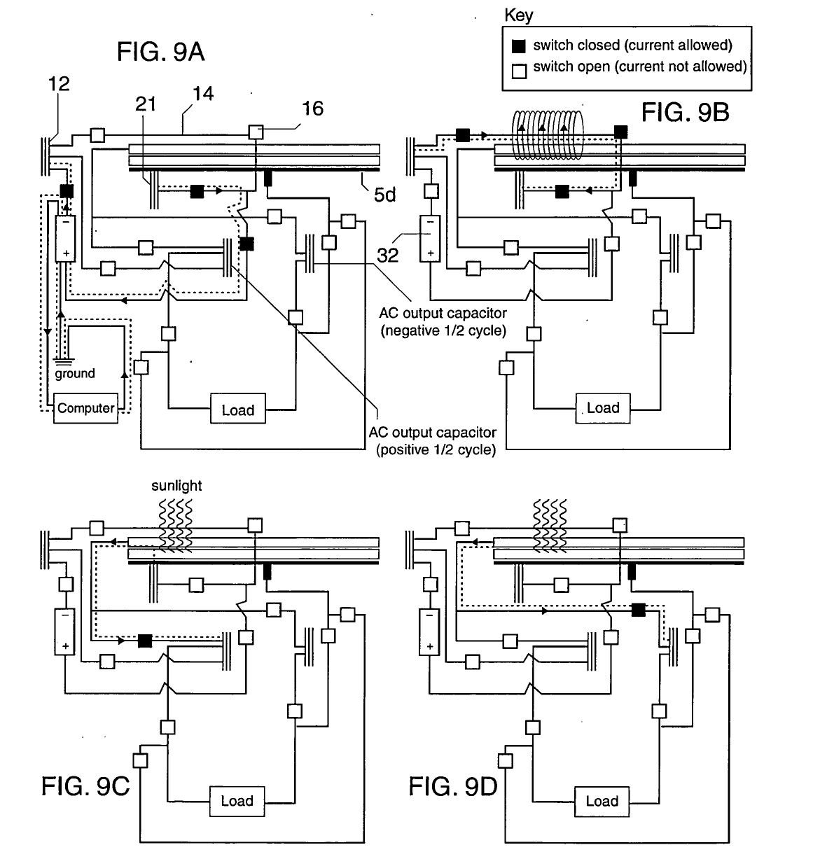

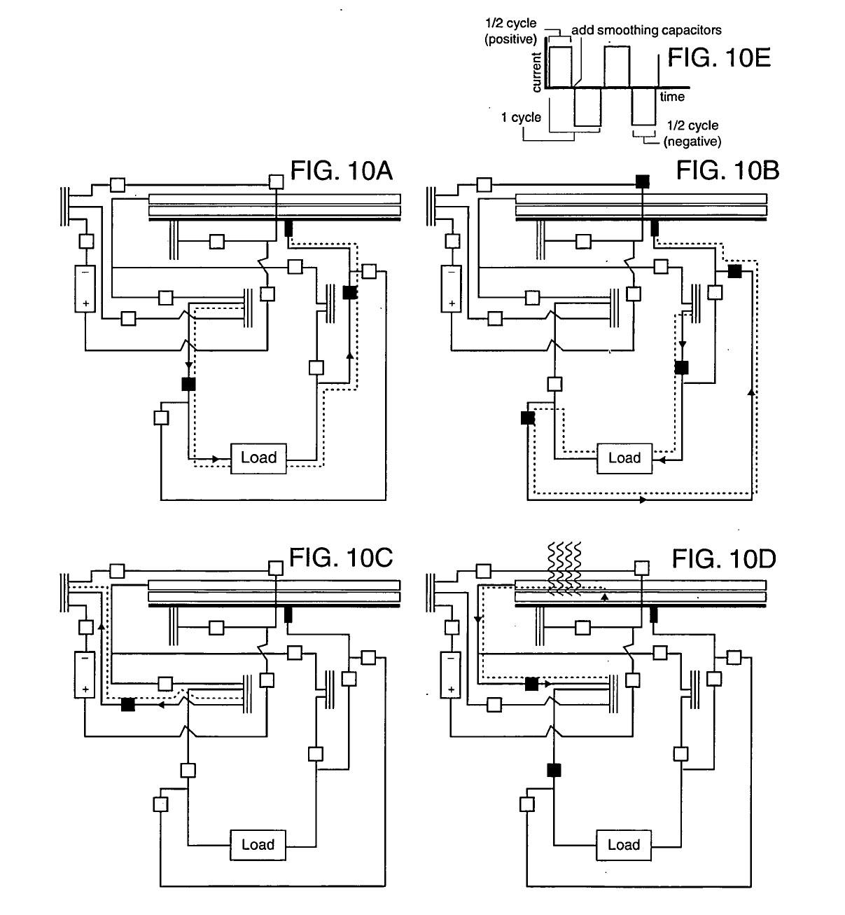

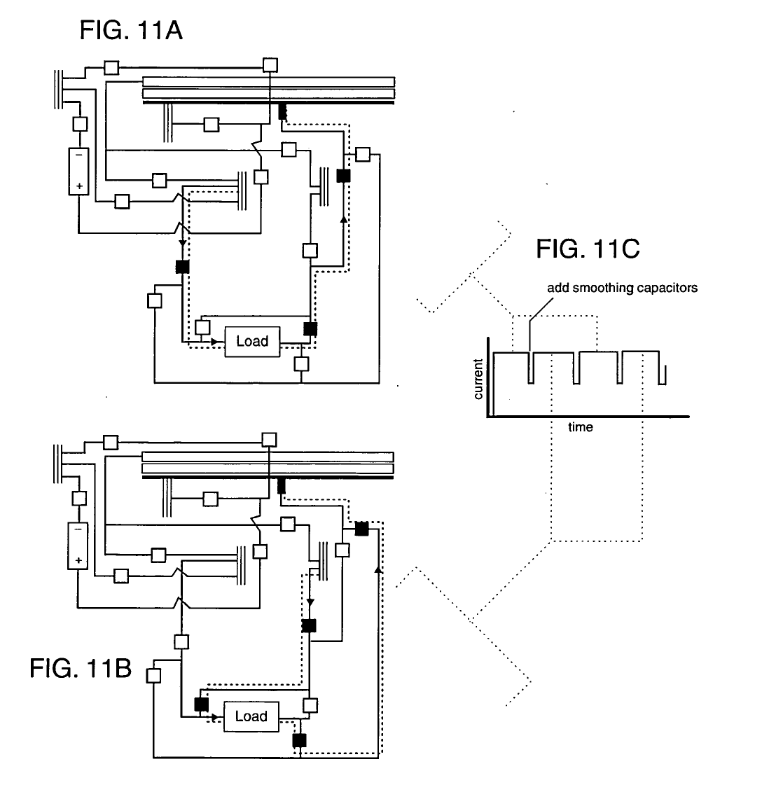

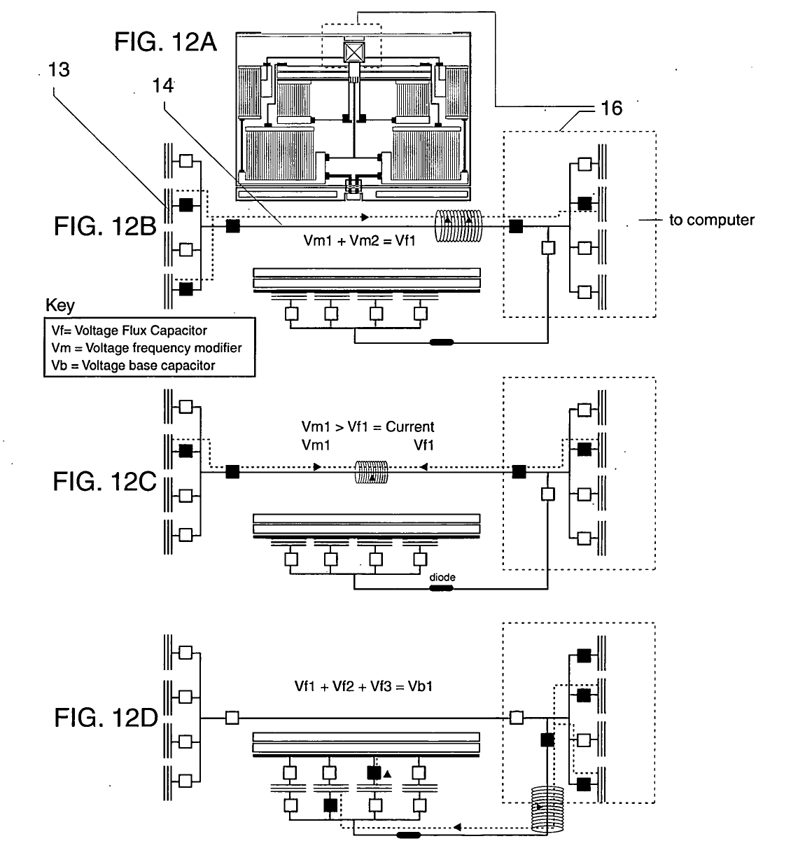

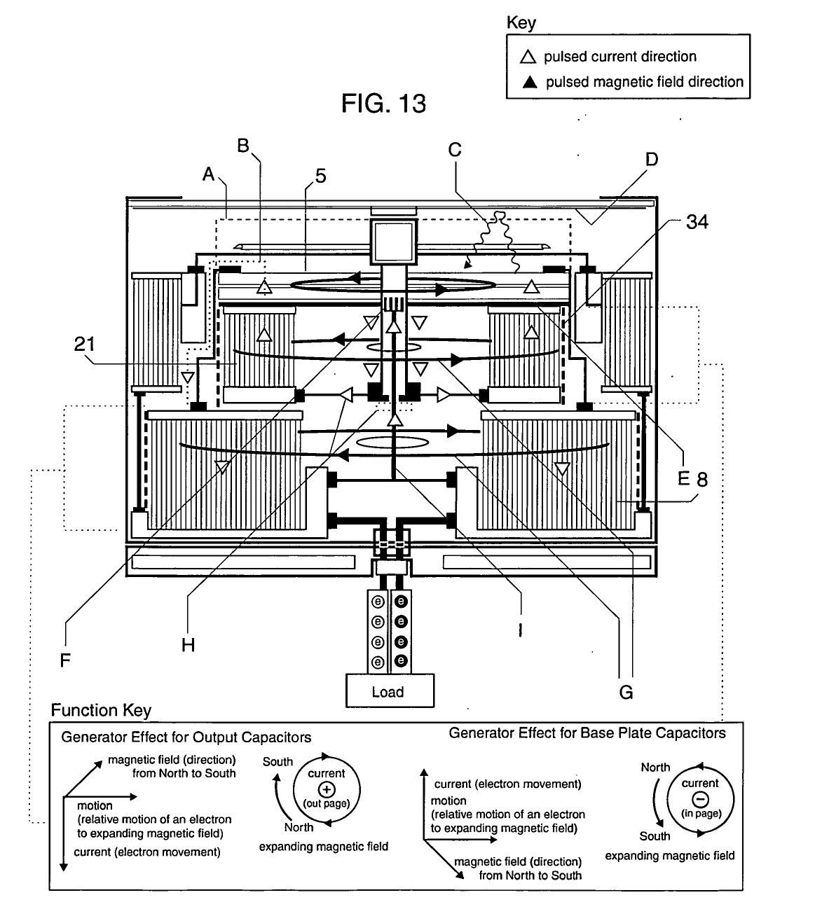

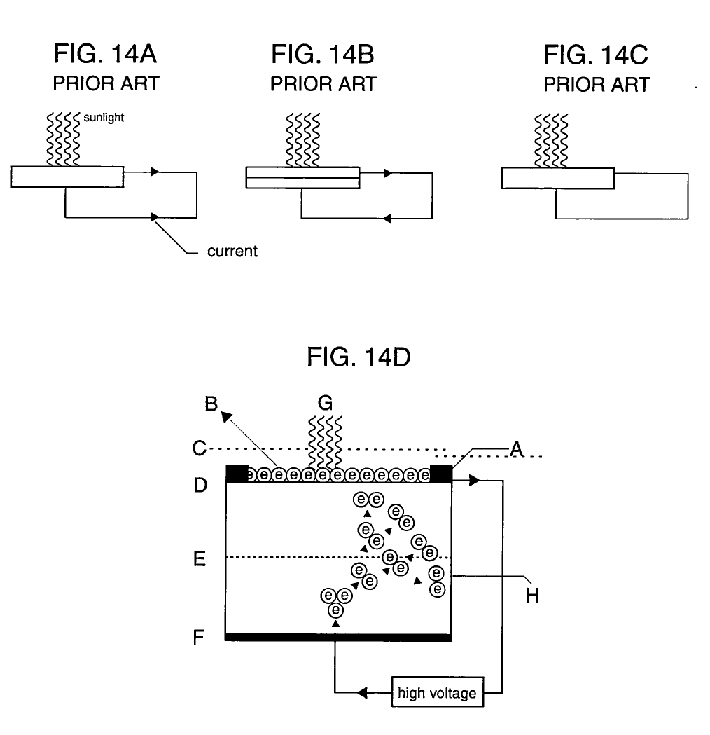

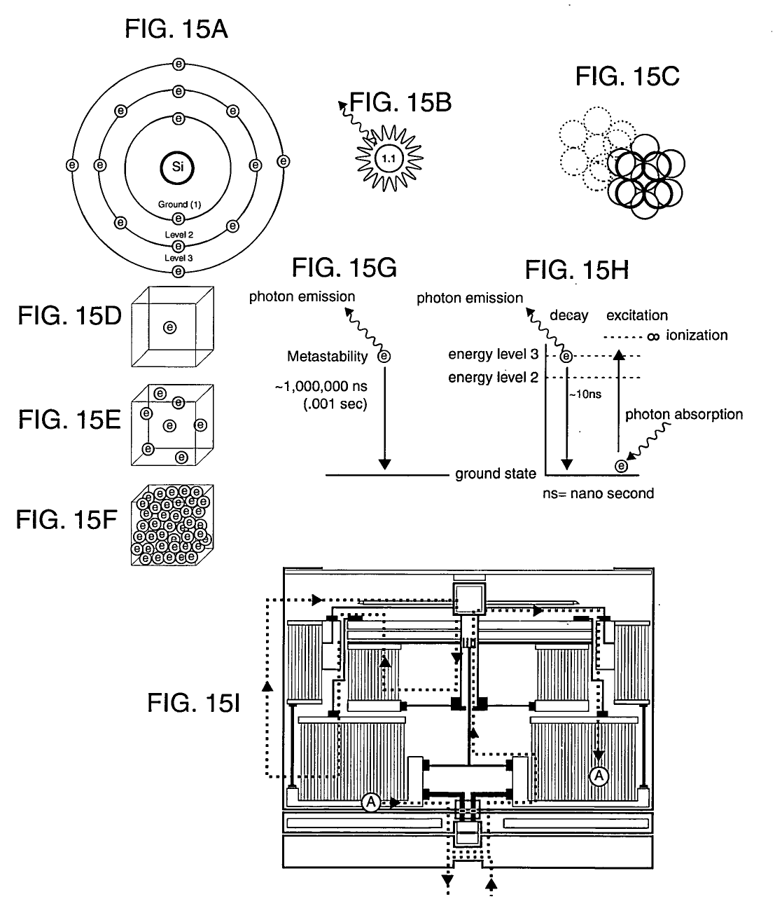

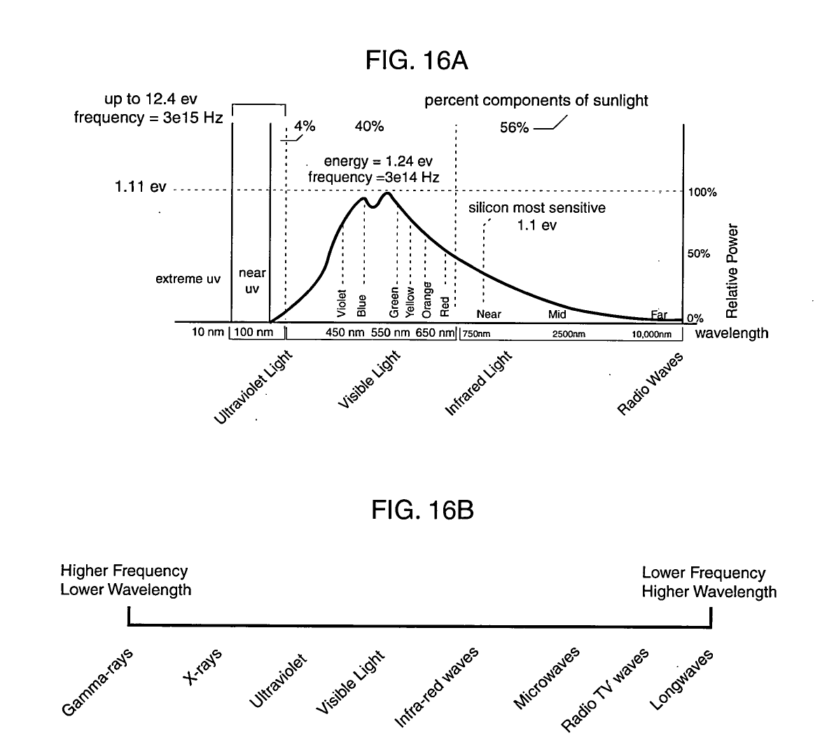

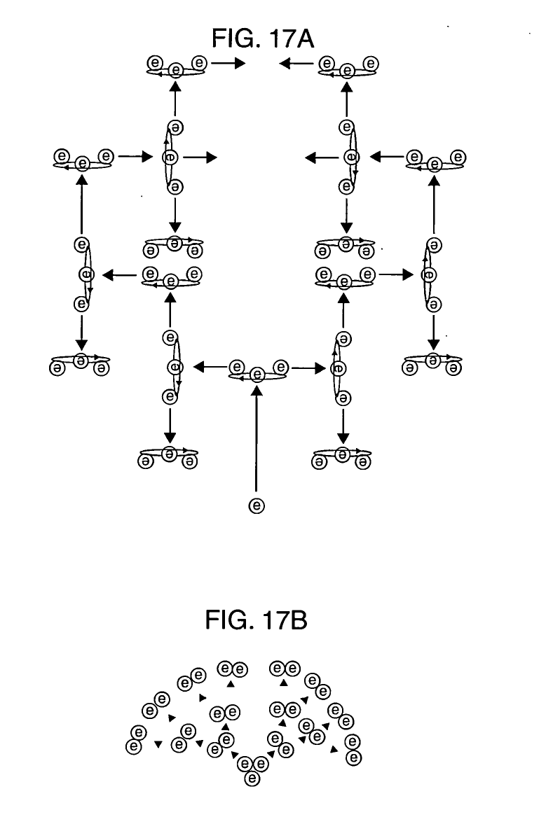

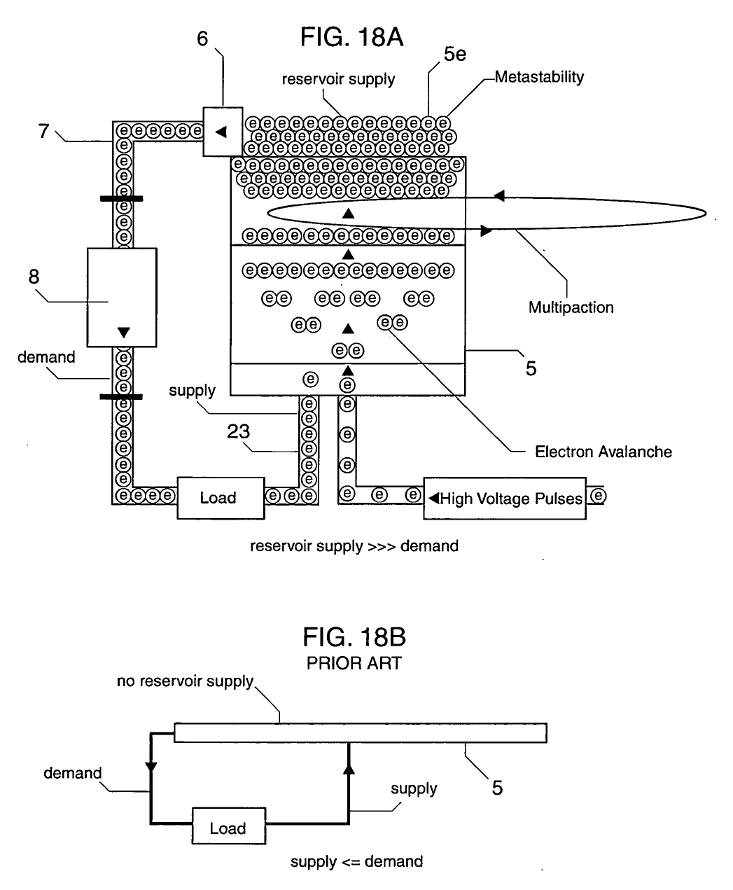

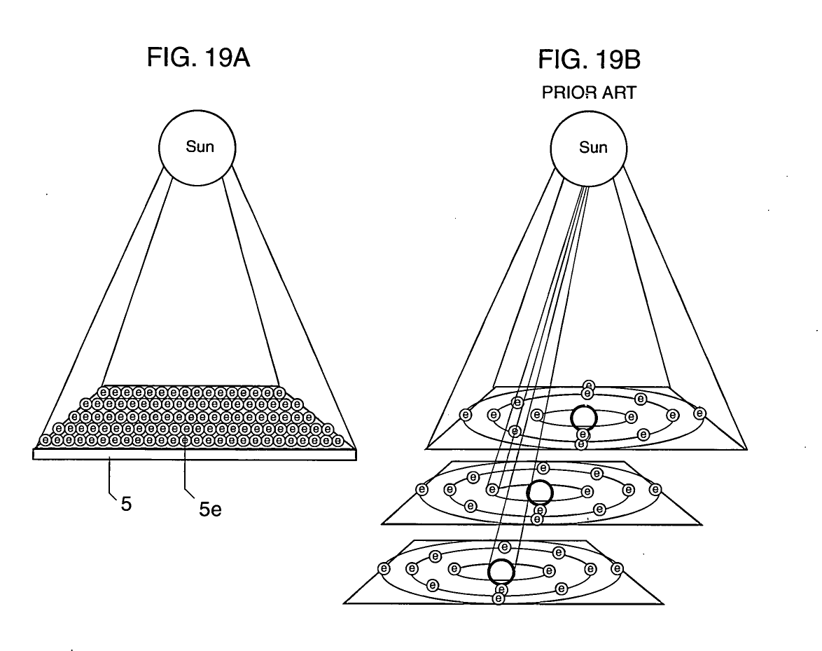

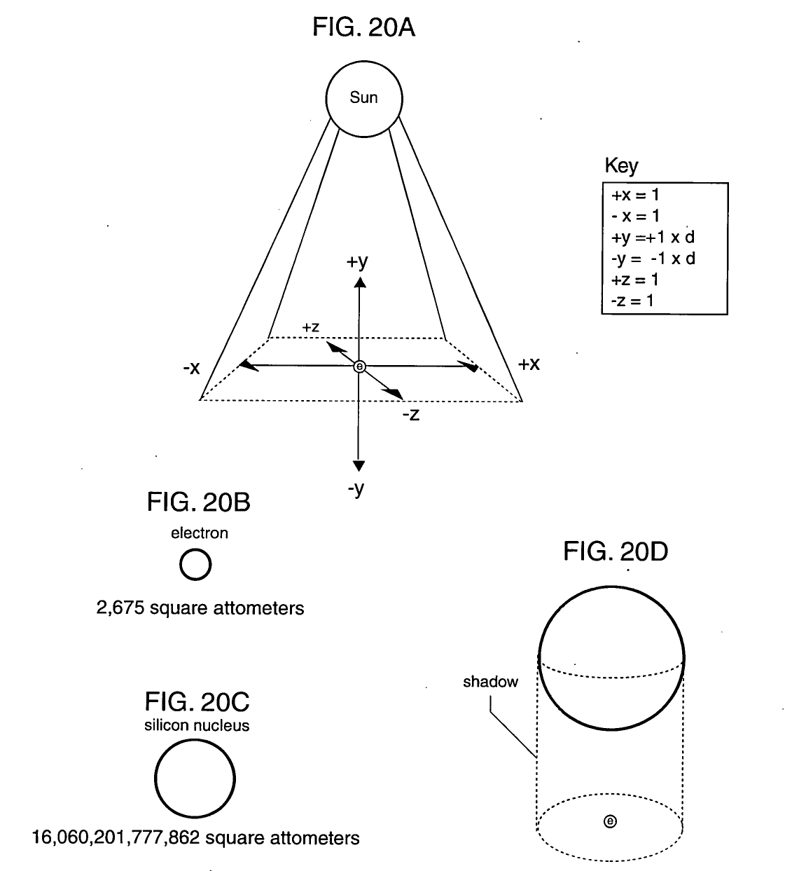

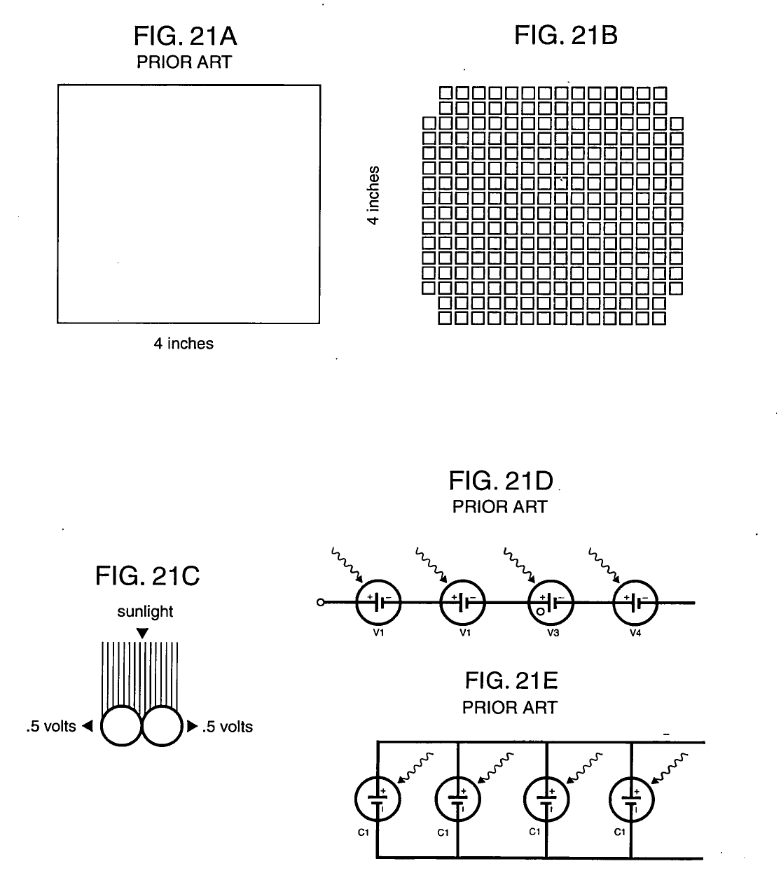

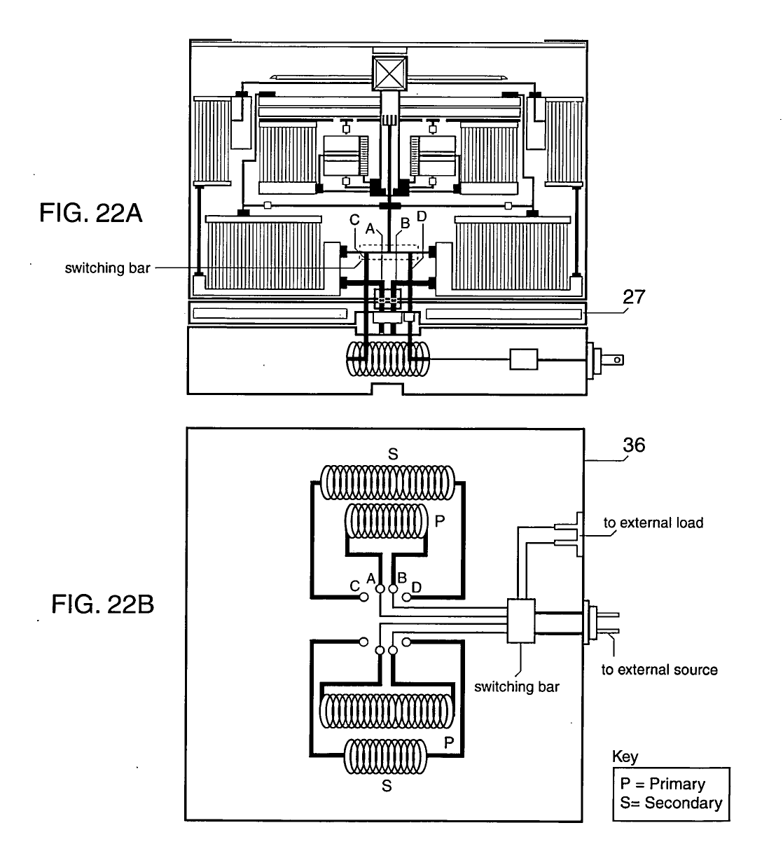

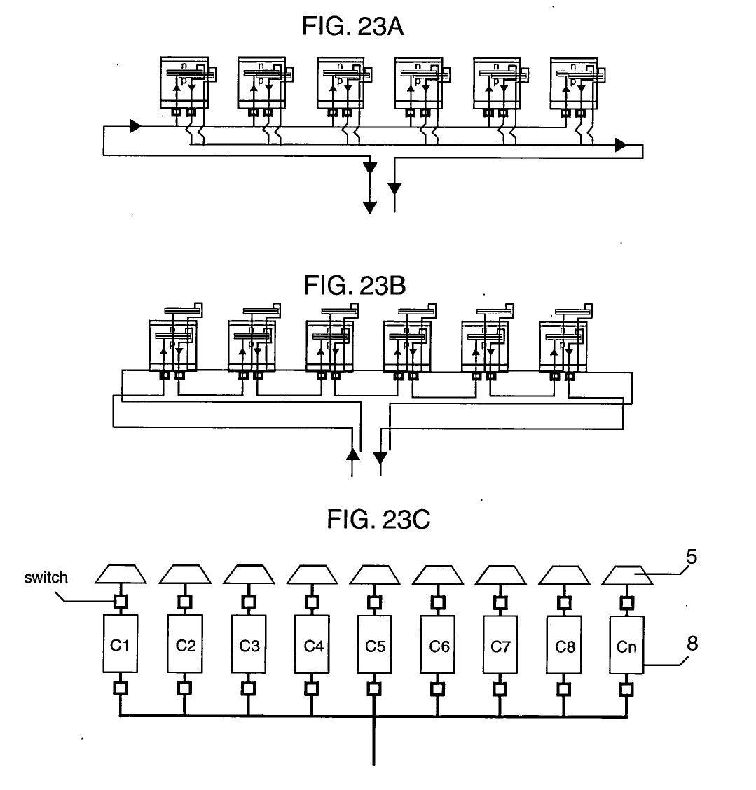

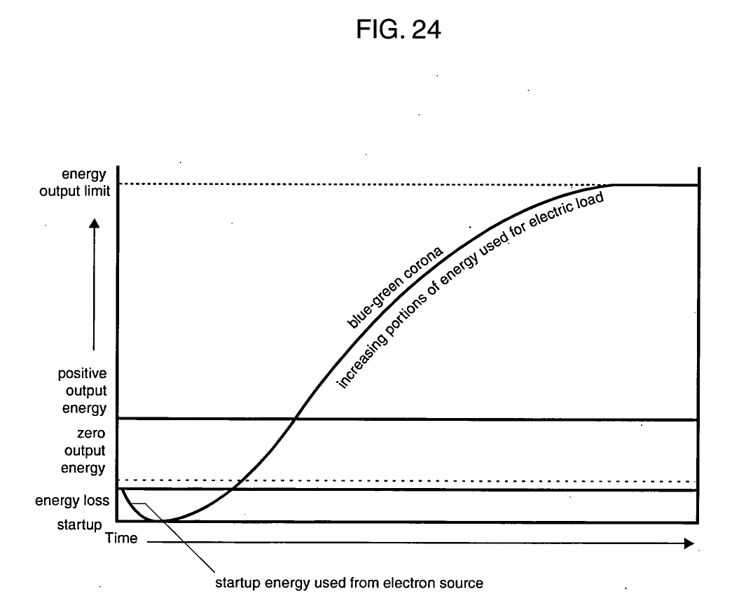

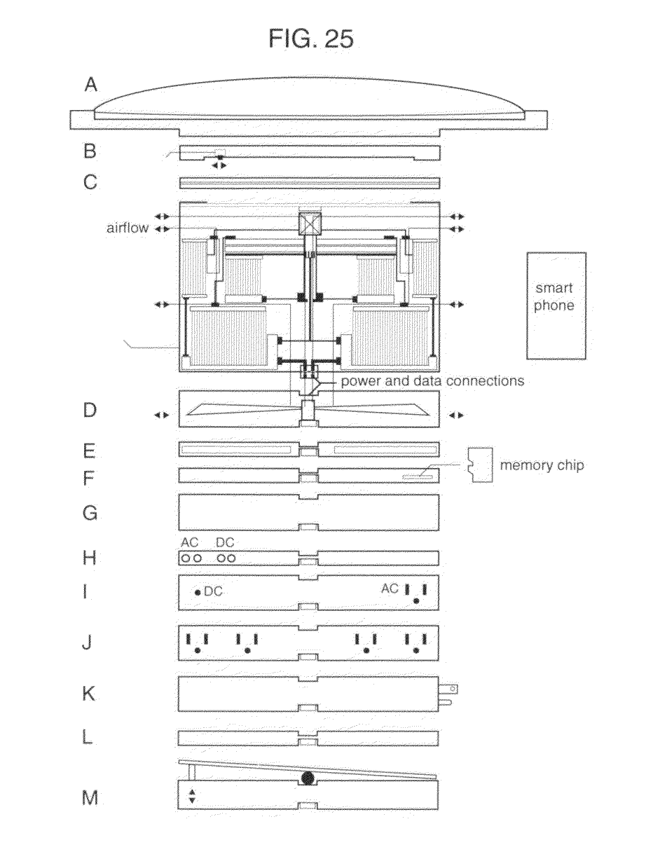

### Preferred Embodiment—FIG. 3

The preferred embodiment of the Flux Capacitor Solar Cell Module (1) involves a module shell (2). The module shell (2) has on its top an opening for the transparent cover (3). The sun intensity tracker (4) sits in the center of the transparent cover (3). Within this module shell (2) exists at least three layers which are the electron excitation layer, the electron return layer and underneath this layer the power output layer. The electron excitation layer involves at least one solar cell (5). For 120 volt operation 240 solar cell slices each with an output voltage of approximately 0.5 volts will yield 120 volts when wired in a parallel circuit configuration. A typical single junction silicon solar cell (5) is comprised of a conducting base (5d) on the bottom, a positive layer (5a) on top of it, followed by the negative layer (5c). The p-n junction (5b) resides between both layers. On the outer top perimeter of each solar cell (5) slice is the electron pool conductor edge (6). An output capacitor charging conductor (7) is connected to each electron pool conductor edge (6). Each output capacitor charging conductor (7) is connected to at least one capacitor in the high voltage output capacitor bank (8). The high voltage output capacitor bank's (8) capacitors are connected to the high output capacitor switching bar (9) and the frequency modifier capacitor switching bar (10). The high output capacitor switching bar (9) is connected to the high voltage output conductor (25). This conductor exits the module shell (2) to supply power to a load. The frequency modifier charging conductor (11) which rises toward the top of the module shell (2) is connected to the frequency modifier capacitor switching bar (10). The frequency modifier charging conductor (11) is connected to the frequency modifier capacitor banks (12) which is connected to the frequency modifier switching bar (13). Moving horizontally towards the center of the module and connected to the frequency modifier switching bar (13) is the frequency modifier conductor (14). Located above and running along the length of the frequency modifier conductor (14) is the frequency modifier field reflector (15). The frequency modifier conductor (14) crosses the top of the solar cell (5) and enters the flux capacitor (16) which sits in the center of the module (1) over the solar cell (5). The flux capacitor (16) having multiple capacitors and switching units is connected to the flux capacitor conductor field up tube (17) which is located directly below it and penetrates down through the solar cell (5). Connected to the bottom of the flux capacitor conductor field up tube (17) around its perimeter is the pipe conductor distributor (18). From here the base plate capacitor conductor (19) extends outward and connects with the high voltage base plate capacitor switching bar (20). The base plate capacitors (21) connect to and sit around the outer edge of the underside of solar cell (5) and connects to the high voltage base plate capacitor switching bar (20).

The base plate feed in conductors (22) run from the high output capacitor switching bar (9) and junction in the center with at least one vertical base plate conductor (23). This base plate conductor (23) runs up through the center of the flux capacitor conductor field up tube (17) and connects to the base plate (5d). The top of the flux capacitor conductor field up tube (17) forming into the slits of the high voltage distribution gate (24). The slits allow the base plate (5d) to enter the interior of the tube and connect to the top of the base plate conductor (23).

The electron source block (28) is located within the ring of base plate capacitors (21) but surrounds the flux capacitor conductor field up tube (17). It is comprised of an electron source material (28a) connected to electron source capacitors (28b). The electron source capacitors (28b) is connected to the electron source capacitor input conductor (28g) which is connected to pipe conductor distributor (18). At the bottom of the source material (28a) connects the electron source input conductor (28f). This electron source input conductor (28f) is connected to the pipe conductor distributor (18) and has at least one electron source input switch (28e) on it. The electron source output conductor (28c) which is connected to the high voltage base plate capacitor switching bar (20) runs from the electron source output switching bar (28d) through the center of the electron source material (28a) and to the electron source capacitor (28b). The electron source base plate conductor (28i) runs from the top of the electron source block (28) to the base of the base plate (5). The electron source base plate switch (28h) being connected to the electron source base plate conductor (28i). An electron source base plate gap (28j) in the base plate (5) exists on either side of the junction point of the electron source base plate conductor (28g) and the base plate (5). These two gaps separate the base plate (5) into three circular sections.

The frequency bypass conductor (29) runs horizontally from the output capacitor charging conductor (11) through a frequency bypass conductor switch (30) into a frequency bypass conductor distributor (31). The frequency bypass conductor distributor (31) is connected to the vertical base plate conductor (23).

At each of the four corners of the module (1) are compartment areas. At the top of the module sits the battery compartment (32) and underneath it sits an electronics compartment (33). Magnetic shielding (34) is located throughout the module (1).

The module power transfer connector (26) connects to the removable computer module (27). A data connection (35) connects the computer module (27) to the Flux Capacitor Solar Cell module (1). There are multiple attachment modules (36) that can connect to the underside of this computer module (27).

### DETAILED DESCRIPTION OPERATION

### Preferred Embodiment—FIG. 3

In its preferred embodiment of operation the Flux Capacitor Solar Cell is started by an energy source either externally or via its batteries which are located in their battery compartments (32). This power starts the computer module (27) which checks the switching systems (9, 10, 13, 20, 28d) and capacitor banks of the module (1). A check of the sun intensity tracker (4) is performed which if pivoting module is connected, pivots the module (1) perpendicular to the sun's rays. This check also allows the computer to calculate the required switching mechanisms and capacitor capacities needed for the desired operation according to the power load and sun intensity. Once the check is completed each solar cell (5) slice provides electrons to the electron pool conductor edge (6) which then provides electrons to the output capacitor charging conductor (7). During start-up some of the electrons will be allowed to detour through the frequency bypass conductor (29). These electrons then travel through the frequency bypass conductor distributor (31) and up through the base plate conductor (23). The electrons then enter the base plate (5) and move into the solar cell's (5) positive layer (5a) where they are exited furthermore by the sun. They then cross the p-n junction and the solar cell's (5) negative layer (5c) and them move horizontally towards the electron pool conductor edge (6). This short circuit process is for the purpose of making the electrons hot through constant electromagnetic radiation exciting.

After this phase the electrons move down the output capacitor charging conductor (7) and into the high voltage output capacitor banks (8). Here the voltage is build up through parallel and series circuitry located in the high voltage base plate capacitor switching bar (20) and high voltage electrons move through the base plate feed in conductors (22) and up through the base plate conductor (23). The high energy electrons then enter the base plate (5d) of the solar cell (5). These electrons are pulsed so that the effects of electron avalanche and multipaction are created within the solar cell (5). Because the electrons pass through only a small base plate (5d) diameter circle, the path of the electron avalanche electrons keeps that of an inverted pyramid.

After a several trips around the circuits to free up even more electrons, the electrons that require more displacement energy the frequency modifier capacitor banks (12) are charged via the frequency modifier switching bar (13) and high voltage output capacitor bank (8). The higher voltage higher excited electrons then flow through the frequency modifier switching bar (13) where capacitors in parallel and series configurations release frequency controlled electrons to the flux capacitor (16) along the frequency modifier conductor (14). The intensity of electromagnetic radiation from the frequency modifier conductor (14) is enhanced by the frequency modifier field reflector (15). The waves from the frequency modifier field reflector (15) also help minimize radiation leakage from the electron pool (5e). The other purpose of the frequency modifier conductor (14) is to produce artificial electromagnetic waves when cloud cover or light dimming occurs. Although a larger quantity of electrons will be used the vast number of electrons that can exist within the electron pool (5e) can supply it. As the electrons move toward the flux capacitor (16), the generator effect created by the expanding magnetic field creates a voltage pressure on the electrons on top of and in the solar cell (5) towards the electron pool conductor edge (6).

The electrons the enter the flux capacitor (16) are then recombined via parallel and series circuitry and capacitors to move down the flux capacitor field up tube (17). As electrons move down this tube, the quickly expanding and slower contracting electromagnetic field produced creates the generator effect which puts upward pressure on the electrons located within the solar cell (5), the base plate capacitors (21) and the electron source block (28). The electrons' pulse frequency and voltage intensity is controlled by the flux capacitor (16). As electrons exit the bottom of the flux capacitor field up tube (17) via the pipe conductor distributor (18) they enter the high voltage base plate capacitor switching bar (20) via the base plate capacitor conductor (19). From here the base plate capacitors (21) are charged. The electrons are pulsed out of the base plate capacitors (21) and into the base plate (5d). This provides electron avalanche effects and multipaction around the outer edge of the solar cells (5). The intensity is controlled so as to be coordinated with the electron flows created from the central base plate conductor (23). At this point the electrons will reach their maximum energy levels and more electrons must be excited by the sun in order to boost up the number of electrons or output current to get the desired wattage. Some of the electrons moving down the flux capacitor up field tube (17) are then sent to the electron source capacitor (28b) via the pipe conductor distributor (18) and electron source capacitor input conductor (28g).

The electrons are then boosted in voltage energy and pulsed at a desired frequency and outputted via the electron source output conductor (28c) to the base plate capacitors (21) through the electron source output switching bar (28d). The purpose of this feature is to enhance and control the frequency of the electrons in the electron source block (28) so that they are removed more efficiently and move through the solar cell (5) more efficiently. Electrons are then routed from the pipe conductor distributor (18) through the electron source input conductor to the electron source block (28). Pulsing is controlled by the electron source input switch (28e). Additional high frequency electrons can be added to the source block via the frequency bypass conductor (29) via the pipe conductor distributor (18) which takes electrons directly from the electron pool which have by-passed any capacitors. The final result is that depending on the source block's (28) thickness and electron frequency energy levels, for every one electron that enters into the source block per each electron source input conductor (28f) there are thousands to tens of thousands of electrons that will exit the block via the electron source base plate conductor (28i). The electron source base plate switch (28h) is a current manipulator in that it could be switch, solid state diode or magnetically operated in order to prevent a backflow of electrons back into the electron source block (28). High energy electrons can now enter the solar cell (5) through the center base plate (5d) section to create an electron avalanche and multipaction. After a period of time this electron source block (28) is cut off from the rest of the circuit. Because the capacitors are filled to capacity and because the electrons cannot return back “home” to the electron source block (28) the electrons must reside on the top of the solar cell (5) which forms an electron pool. This pool which mimics a dam serves as a reservoir in order to supply adequate quantities of electrons to the high voltage output capacitor banks (8). Voltage is a constant in a solar cell regardless of size. Because the sun's electromagnetic waves give intrinsic voltage properties to each and every electron, the solar cells (5) and their capacitors wired together can create the high (120) voltages necessary and the pool supplies the proper coulombs of electrons.

This quantity of high voltage energy electrons are now sent in an alternating current method through the high voltage output conductor (25). This high voltage output conductor (25) exits the center part of the bottom of the module (1). Conductors from a transformer module run through the computer module (27) to connect to the high voltage output conductors (25). Within the transformer module the conductor is coiled to the desired number of turns for step down or step up voltage and currents. Although the module (1) can supply energy directly, the purpose of the transformer module is to allow the electrons to maintain their high frequency energy so that the electrons can tunnel back through the solar cell (5) more efficiency and thus no electrons leave the module (1). Additional attachment modules (36) can be connected to achieve more performance and use objectives.

The end result is a solar module in which the electrons do not leave it to make it more efficient and any needed energy is transferred. The only thing which limits power output is the heat capacity of the materials.

### CONCLUSION, RAMIFICATIONS AND SCOPE

In conclusion the Flux Capacitor Solar Cell is able to produce more power in a smaller package by isolating and maximizing the elements of current and voltage and utilizing the element of resistance in the form of gates and capacitors. Because of the compartmentalized structure of the Flux Capacitor Solar Cell, different areas of the module can perform different functions yet relate back to and reinforce another function. The 1000 watts per square meter limit that has been attached to the power of the sun only applies to diodes. Conventional passive solar cells operate under this law because they are diodes and such calculations and applications cannot be applied universally to the nature of particle physics and achieve maximum results. By observing that any particle at any point in any electromagnetically radiated horizontal plane will experience the same excitation level and by knowing the number of particles that can fit within that energized area, a base starting point for the maximum amount of power the can be produced is created.

### Additional Embodiments and Ramifications

There are additional embodiments and ramifications that apply to this technology such as removing the electron source block or adding an external power source. There are also numerous module attachments that can assist the Flux Capacitor Solar Cell in achieving even greater levels of operation.

### Other Embodiments and Ramifications

The procedures, elements and assemblies described herein and any changes made in the steps or the sequence of steps of the methods described herein can be made without departing from the spirit and scope of the invention as defined in the following claims.

1. What is claimed is at least one module means capable of supplying electron power to at least one resistive load means in which a percentage of said electron power is created by a percentage of at least one frequency of incident electromagnetic energy energizing said electrons which move through at least one interconnectable circuit means. Said module means being comprised of:
(a) at least one volume of material containing at least one electron. A percentage of said volume of material having a means to be exposed to a percentage of said electromagnetic energy;
(b) the volume of material having at least one means to allow at least one electron to access at least one electron storage means via at least one electron conduction means. Said electron storage means having at least one electron access point means;
(c) the electron storage means having at least one means to allow at least one electron to access a percentage of at least one of the volume of materials via at least one electron conduction means;
(d) at least one current manipulating gate means having at least one means to control electron movement in at least one electron conduction means;
(e) at least one electron conduction means having at least one means to allow at least one electron an access means to at least one resistive load means;
(f) at least one means to control at least one current manipulating gate means;
(g) at least one means to connect to at least one computer means. A percentage of at least one of the computer means capacity controlling at least one means that controls at least one current manipulating gate means; and
(h) at least one electron source means having at least one means of allowing at least one electron to access it through at least one current manipulating gate means via at least one electron conduction means.

2) What is claimed is claim 1 in which the electromagnetic energy is solar energy.

3) What is claimed is claim 1 in which the volume of material is a solar cell.

4) What is claimed is claim 1 in which the volume of material is homogeneous.

5) What is claimed is claim 1 in which the volume material is heterogeneous.

6) What is claimed is claim 1 in which the current manipulating gate means is operated by a voltage means.

7) What is claimed is claim 1 in which the current manipulating gate means is operated by a magnetic field means.

8) What is claimed is claim 1 in which the resistive load is an inductance means.

9) What is claimed is claim 1 in which the resistive load is a resistance means.

10) What is claimed is claim 1 in which the resistive load is a capacitance means.

11) What is claimed is claim 1 in which a percentage of the incident electromagnetic energy is created by a means other than the incident electromagnetic energy.

12) What is claimed is claim 1 in which said supplied electron power is alternating current.

13) What is claimed is claim 1 in which said supplied electron power is direct current.

14) What is claimed is claim 1 having at least one magnetic field creation means to apply pressure to at least one electron in at least one functional direction.

15) What is claimed is claim 1 in which electron power is supplied to at least one functioning means of said module.

16) What is claimed is claim 1 in which the module has at least one electron power access means with at least one other electron powering module means.

17) What is claimed is claim 1 in which at least one attachment module having a function means applicable to the module has at least one interaction means with the module.

18) What is claimed is claim 17 in which at least one additional attachment module having a function means applicable to the module has at least one interaction means with at least one of said attachment modules.

19. What is claimed is at least one module means capable of supplying electron power to at least one resistive load means in which a percentage of said electron power is created by a percentage of at least one frequency of incident electromagnetic energy energizing said electrons which move through at least one interconnectable circuit means. Said module means being comprised of:
(a) at least one volume of material containing at least one electron. A percentage of said volume of material having a means to be exposed to a percentage of said electromagnetic energy;
(b) the volume of material having at least one means to allow at least one electron to access at least one electron storage means via at least one electron conduction means. Said electron storage means having at least one electron access point means;
(c) the electron storage means having at least one means to allow at least one electron to access a percentage of at least one of the volume of materials via at least one electron conduction means;
(d) at least one current manipulating gate means having at least one means to control electron movement in at least one electron conduction means;
(e) at least one electron conduction means having at least one means to allow at least one electron an access means to at least one resistive load means;
(f) at least one means to control at least one current manipulating gate means;
(g) at least one means to connect to at least one computer means. A percentage of at least one of the computer means capacity controlling at least one means that controls at least one current manipulating gate means;
(h) at least one electron source means having at least one means of allowing at least one electron to access it through at least one current manipulating gate means via at least one electron conduction means; and
(i) at least one power input means to accept electron power from at least one electron power source means.

20. What is claimed is a method of supplying electron power to at least one resistive load means in which a percentage of said electron power is created by a percentage of at least one frequency of incident electromagnetic energy upon at least one of said electrons. The method is controlled by at least one computer means which controls at least one means to control electron movement in at least one interconnectable circuit means. The method being comprised of:
(a) a percentage of at least one volume of material which contains at least one electron being exposed to a percentage of said electromagnetic energy;
(b) said volume of material having a means to allow at least one of the electrons to access at least one electron storage means through at least one electron current manipulating gate means via at least one electron conduction means;
(c) said electron storage means having at least one of its electrons moving out of it through at least one electron current manipulating gate means and through at least one resistive load means via at least one electron conduction means;
(d) at least one of the electrons having access to at least one of the volume of materials through at least one electron current manipulating gate means via at least one electron conduction means; and
(e) for a percentage of the time of the duration of said method at least one electron source means allowing at least one electron to access it through at least one current manipulating gate means via at least one electron conduction means,
whereas there is no particular operational sequence.

21. What is claimed is at least one module means capable of supplying electron power to at least one resistive load means in which a percentage of said electron power is created by a percentage of at least one frequency of incident electromagnetic energy energizing said electrons which move through at least one interconnectable circuit means. Said module means being comprised of:
(a) at least one volume of material containing at least one electron. A percentage of said volume of material having a means to be exposed to a percentage of said electromagnetic energy;
(b) the volume of material having at least one means to allow at least one electron to access at least one electron storage means via at least one electron conduction means. Said electron storage means having at least one electron access point means;
(c) the electron storage means having at least one means to allow at least one electron to access a percentage of at least one of the volume of materials via at least one electron conduction means;
(d) at least one current manipulating gate means having at least one means to control electron movement in at least one electron conduction means;
(e) at least one electron conduction means having at least one means to allow at least one electron an access means to at least one resistive load means;
(f) at least one means to control at least one current manipulating gate means; and
(g) at least one means to connect to at least one computer means. A percentage of at least one of the computer means capacity controlling at least one means that controls at least one current manipulating gate means.

22. What is claimed is at least one module means capable of supplying electron power to at least one resistive load means in which a percentage of said electron power is created by a percentage of at least one frequency of incident electromagnetic energy energizing said electrons which move through at least one interconnectable circuit means. Said module means being comprised of:
(a) at least one volume of material containing at least one electron. A percentage of said volume of material having a means to be exposed to a percentage of said electromagnetic energy;
(b) the volume of material having at least one means to allow at least one electron to access at least one electron storage means via at least one electron conduction means. Said electron storage means having at least one electron access point means;
(c) the electron storage means having at least one means to allow at least one electron to access a percentage of at least one of the volume of materials via at least one electron conduction means;
(d) at least one current manipulating gate means having at least one means to control electron movement in at least one electron conduction means;
(e) at least one electron conduction means having at least one means to allow at least one electron an access means to at least one resistive load means;
(f) at least one means to control at least one current manipulating gate means; and
(g) at least one means to connect to at least one computer means. A percentage of at least one of the computer means capacity controlling at least one means that controls at least one current manipulating gate means; and
(h) at least one power input means to accept electron power from at least one electron power source means.

23. What is claimed is a method of supplying electron power to at least one resistive load means in which a percentage of said electron power is created by a percentage of at least one frequency of incident electromagnetic energy upon at least one of said electrons. The method is controlled by at least one computer means which controls at least one means to control electron movement in at least one interconnectable circuit means. The method being comprised of:
(a) a percentage of at least one volume of material which contains at least one electron being exposed to a percentage of said electromagnetic energy;
(b) said volume of material having a means to allow at least one of the electrons to access at least one electron storage means through at least one electron current manipulating gate means via at least one electron conduction means;
(c) said electron storage means having at least one of its electrons moving out of it through at least one electron current manipulating gate means and through at least one resistive load means via at least one electron conduction means;
(d) at least one of the electrons having access to at least one of the volume of materials through at least one electron current manipulating gate means via at least one electron conduction means; and (e) for a percentage of the time of th e duration of said method at least one electron source means allowing at least one electron to access it through at least one current manipulating gate means via at least one electron conduction means; and
(f) using at least one electron power input means in at least one of the conductor means,
whereas there is no particular operational sequence.
